(19) United States
(12) Patent Application Publication
(10) Pub. No.: US 2021/0405526 A1
(43) Pub. Date: Dec. 30, 2021

(54) COLORING COMPOSITION, CURED FILM, STRUCTURE BODY, COLOR FILTER, AND DISPLAY DEVICE

(71) Applicant: FUJIFILM Corporation, Tokyo (JP)

(72) Inventor: Keiji YAMAMOTO, Shizuoka (JP)

(73) Assignee: FUJIFILM Corporation, Tokyo (JP)

(21) Appl. No.: 17/469,882

(22) Filed: Sep. 9, 2021

Related U.S. Application Data
(63) Continuation of application No. PCT/JP2020/012684, filed on Mar. 23, 2020.

(30) Foreign Application Priority Data
Mar. 28, 2019 (JP) 2019-063501

(51) Int. Cl. G03F 7/00; G03F 7/029; G02B 5/22

(52) U.S. Cl. CPC G03F 7/0007; H01L 27/322; G02B 5/223; G03F 7/029

(57) ABSTRACT

Provided are a coloring composition including a colorant, a polymerizable compound, and a photopolymerization initiator, in which the colorant includes at least one selected from C. I. Pigment Blue 15:3 or C. I. Pigment Blue 15:4, and C. I. Pigment Yellow 150, and contains 35 to 55 parts by mass of C. I. Pigment Blue 15:3 and C. I. Pigment Blue 15:4 in total with respect to 100 parts by mass of C. I. Pigment Yellow 150, and the coloring composition has a minimum absorbance in a wavelength range of 495 to 525 nm among absorbances to light having a wavelength of 400 to 700 nm; a cured film formed of the coloring composition; a structure body; a color filter; and a display device.

### CROSS-REFERENCE TO RELATED APPLICATIONS

This application is a Continuation of PCT International Application No. PCT/JP2020/012684 filed on Mar. 23, 2020, which claims priority under 35 U.S.C § 119(a) to Japanese Patent Application No. 2019-063501 filed on Mar. 28, 2019. Each of the above application(s) is hereby expressly incorporated by reference, in its entirety, into the present application.

### BACKGROUND OF THE INVENTION

### 1. Field of the Invention

The present invention relates to a coloring composition. More specifically, the present invention relates to a coloring composition used for forming a green pixel of a color filter, or the like. The present invention further relates to a cured film formed of the coloring composition, a structure body, a color filter, and a display device.

### 2. Description of the Related Art

In various display devices, a color filter is generally used to colorize display images. In addition, in the color filter, an attempt is made to adjust spectroscopy by using a plurality of pigments in combination.

For example, JP2017-194662A discloses that, in a green photosensitive composition for forming a green filter segment, green pigments such as Color Index (C. I.) Pigment Green 7, 10, 36, 37, and 58, and aluminum phthalocyanine pigment can be used, and further, a yellow pigment can be used in combination. In addition, in Examples of JP2017-194662A, a photosensitive composition including C. I. Pigment Green 58 and C. I. Pigment Yellow 150 is used as a green photosensitive composition.

JP2018-163284A discloses an invention relating to a green photosensitive coloring composition for an organic electroluminescence (EL) display device including, as a colorant, a predetermined aluminum phthalocyanine pigment, and C. I. Pigment Yellow 185.

### SUMMARY OF THE INVENTION

In a color filter, it has been desired that color separation property is high and light resistance is excellent. These characteristics have been demanded at a higher level in recent years.

From intensive studies with regard to the green photosensitive composition disclosed in JP2017-194662A and the green photosensitive coloring composition for organic EL display device disclosed in JP2018-163284A, the present inventor has found that a cured film obtained by using these green photosensitive compositions has room for further improvement in color separation property from other colors and light resistance.

Therefore, an object of the present invention is to provide a coloring composition with which a cured film having excellent light resistance and color separation property from other colors can be formed. Another object of the present invention is to provide a cured film formed of the above-described coloring composition, a structure body, a color filter, and a display device.

According to the studies conducted by the present inventor, it has been found that the above-described object can be achieved by using a coloring composition which will be described later, thereby leading to completion of the present invention. The present invention provides the following.

<1> A coloring composition comprising:

a colorant;

a polymerizable compound; and

a photopolymerization initiator,

in which the colorant includes at least one selected from Color Index Pigment Blue 15:3 or Color Index Pigment Blue 15:4, and Color Index Pigment Yellow 150, and contains 35 to 55 parts by mass of Color Index Pigment Blue 15:3 and Color Index Pigment Blue 15:4 in total with respect to 100 parts by mass of Color Index Pigment Yellow 150,

the coloring composition has a minimum absorbance in a wavelength range of 495 to 525 nm among absorbances to light having a wavelength of 400 to 700 nm,

in a case where an absorbance to light having a wavelength of 450 nm is defined as 1, wavelengths at which an absorbance is 0.14 exist in a range of 474 to 494 nm and a range of 530 to 570 nm, respectively, and

A⁴⁵⁰/A⁶²⁰, which is a ratio of an absorbance A⁴⁵⁰ to light having a wavelength of 450 nm and an absorbance A⁶²⁰ to light having a wavelength of 620 nm, is 1.08 to 2.05.

<2> The coloring composition according to <1>,

in which, in a case where the absorbance to light having a wavelength of 450 nm is defined as 1, a difference between a wavelength on a long wavelength side where an absorbance is 0.4 and a wavelength on a short wavelength side where an absorbance is 0.4 is 80 to 118 nm.

<3> The coloring composition according to <1> or <2>,

in which a total content of Color Index Pigment Blue 15:3, Color Index Pigment Blue 15:4, and Color Index Pigment Yellow 150 in the colorant is 80 to 100 mass %.

<4> The coloring composition according to any one of <1> to <3>,

in which a content of the colorant in a total solid content of the coloring composition is 20 mass % or more.

<5> The coloring composition according to any one of <1> to <4>,

in which the polymerizable compound includes a polymerizable compound having three or more ethylenically unsaturated bond-containing groups.

<6> The coloring composition according to any one of <1> to <5>,

in which the polymerizable compound includes a polymerizable compound having an ethylenically unsaturated bond-containing group and an alkyleneoxy group.

<7> The coloring composition according to any one of <1> to <6>,

in which the photopolymerization initiator contains an oxime compound.

<8> The coloring composition according to any one of <1> to <6>,

in which the photopolymerization initiator contains an oxime compound and a hydroxyalkylphenone compound.

<9> The coloring composition according to any one of <1> to <8>, further comprising:

a resin including a repeating unit derived from a compound represented by Formula (I),

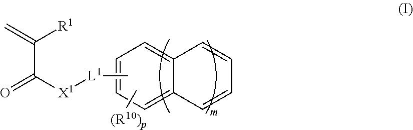

in the formula, X¹ represents O or NH,

R¹ represents a hydrogen atom or a methyl group,

L¹ represents a divalent linking group,

R¹⁰ represents a substituent,

m represents an integer of 0 to 2, and

p represents an integer of 0 or more.

<10> The coloring composition according to any one of <1> to <9>, further comprising:

a compound including a furyl group.

<11> The coloring composition according to any one of <1> to <10>,

in which the coloring composition is a coloring composition for forming a green pixel of a color filter.

<12> The coloring composition according to any one of <1> to <11>,

in which the coloring composition is a coloring composition for a display device.

<13> The coloring composition according to any one of <1> to <12>,

in which the coloring composition is used for forming a cured film at a temperature of 150° C. or lower throughout entire steps.

<14> A cured film obtained by using the coloring composition according to any one of <1> to <13>.

<15> A structure body comprising:

a green pixel;

a red pixel; and

a blue pixel,

in which the green pixel is obtained by using the coloring composition according to any one of <1> to <13>.

<16> A color filter comprising:

the cured film according to <14>.

<17> A display device comprising:

the cured film according to <14>.

According to the present invention, it is possible to provide a coloring composition with which a cured film having excellent light resistance and color separation property from other colors can be formed. In addition, according to the present invention, it is possible to provide a cured film formed of the above-described coloring composition, a structure body, a color filter, and a display device.

### DESCRIPTION OF THE PREFERRED EMBODIMENTS

Hereinafter, the details of the present invention will be described.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. In addition, generally, examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, the numerical value range expressed by “to” means that the numerical values described before and after “to” are included as a lower limit value and an upper limit value, respectively.

In the present specification, a total solid content denotes the total mass of all the components of the composition excluding a solvent.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, the term “step” denotes not only an individual step but also a step which is not clearly distinguishable from another step as long as an effect expected from the step can be achieved.

In the present specification, a weight-average molecular weight (Mw) and a number-average molecular weight (Mn) are each defined as a value in terms of polystyrene through measurement by means of gel permeation chromatography (GPC).

<Coloring Composition>

The coloring composition according to the embodiment of the present invention includes a colorant, a polymerizable compound, and a photopolymerization initiator, in which the colorant includes at least one selected from Color Index Pigment Blue 15:3 or Color Index Pigment Blue 15:4, and Color Index Pigment Yellow 150, and contains 35 to 55 parts by mass of Color Index Pigment Blue 15:3 and Color Index Pigment Blue 15:4 in total with respect to 100 parts by mass of Color Index Pigment Yellow 150, the coloring composition has a minimum absorbance in a wavelength range of 495 to 525 nm among absorbances to light having a wavelength of 400 to 700 nm, in a case where an absorbance to light having a wavelength of 450 nm is defined as 1, wavelengths at which an absorbance is 0.14 exist in a range of 474 to 494 nm and a range of 530 to 570 nm, respectively, and A⁴⁵⁰/A⁶²⁰, which is a ratio of an absorbance A⁴⁵⁰ to light having a wavelength of 450 nm and an absorbance A⁶²⁰ to light having a wavelength of 620 nm, is 1.08 to 2.05.

In the coloring composition according to the embodiment of the present invention, since the colorant which includes at least one selected from Color Index Pigment Blue 15:3 or Color Index Pigment Blue 15:4, and Color Index Pigment Yellow 150, and contains 35 to 55 parts by mass of Color Index Pigment Blue 15:3 and Color Index Pigment Blue 15:4 in total with respect to 100 parts by mass of Color Index Pigment Yellow 150 is used, and the predetermined absorbance characteristics are satisfied, it is possible to form a cured film suitable for a green pixel having excellent light resistance and spectral characteristics excellent in color separation property from red and blue. In particular, it is possible to form a cured film having high light transmittance in a wavelength range of 495 to 525 nm and high shielding property against light in a wavelength range of 400 to 460 nm and light in a wavelength range of 590 to 650 nm.

An absorbance Aλ at a wavelength λ is defined by the following equation (Ab1).

Aλ=−log(Tλ/100) (Ab1)

A) is an absorbance at the wavelength λ and Tλ is a transmittance (%) at the wavelength λ.

In the present invention, the value of the absorbance may be a value measured in the form of a solution, or may be a value measured in the form of a cured film formed using a coloring composition. In a case where the absorbance is measured in a state of a film, it is preferable to measure the absorbance using a film (cured film) which is obtained by applying a coloring composition to a glass substrate by a method such as spin coating, drying the coloring composition at 100° C. for 2 minutes using a hot plate or the like, exposing the coloring composition with i-rays under conditions of a light illuminance of 20 mW/cm² and an exposure amount of 1 J/cm², heating on a hot plate at 100° C. for 20 minutes, and allowing it to cool to normal temperature. The absorbance can be measured using a known spectrophotometer of the related art.

The coloring composition according to the embodiment of the present invention has a minimum absorbance in a wavelength range of 495 to 525 nm among absorbances to light having a wavelength of 400 to 700 nm, and it is preferable to have a minimum absorbance in a wavelength range of 500 to 520 nm, more preferable to have a minimum absorbance in a wavelength range of 502 to 515 nm, and still more preferable to have a minimum absorbance in a wavelength range of 504 to 512.5 nm. Hereinafter, among the absorbances to light having a wavelength of 400 to 700 nm, the wavelength exhibiting the minimum absorbance is also referred to as a wavelength λmin.

In a case where an absorbance of the coloring composition according to the embodiment of the present invention to light having a wavelength of 450 nm is defined as 1, wavelengths at which an absorbance is 0.14 exist in a range of 474 to 494 nm and a range of 530 to 570 nm, respectively. From the viewpoint of color separation property, it is preferable that a wavelength (hereinafter, also referred to as λ1) on the short wavelength side, at which the absorbance is 0.14, exists in a range of 478 to 490 nm, it is more preferable to exist in a range of 480 to 488 nm, and it is still more preferable to exist in a range of 482 to 486 nm. In addition, from the viewpoint of color separation property, it is preferable that a wavelength (hereinafter, also referred to as 2) on the long wavelength side, at which the absorbance is 0.14, exists in a range of 534 to 566 nm, it is more preferable to exist in a range of 536 to 562 nm, and it is still more preferable to exist in a range of 538 to 558 nm.

From the viewpoint of color separation property, the difference (λ2−λ1) between λ2 and λ1 is preferably 36 to 96 nm, more preferably 40 to 80 nm, and still more preferably 51 to 71 nm. In addition, from the viewpoint of color separation property, the difference (λmin−λ1) between λmin and λ1 is preferably 10 to 40 nm, more preferably 15 to 35 nm, and still more preferably 20 to 30 nm. In addition, from the viewpoint of color separation property, the difference (λ2−λmin) between λ2 and λmin is preferably 25 to 55 nm, more preferably 30 to 50 nm, and still more preferably 35 to 45 nm.

In the coloring composition according to the embodiment of the present invention, in a case where an absorbance to light having a wavelength of 450 nm is defined as 1, from the viewpoint of color separation property, the difference (λ4−λ3) between a wavelength (hereinafter, also referred to as %4) on the long wavelength side, at which an absorbance is 0.4, and a wavelength (hereinafter, also referred to as λ3) on the short wavelength side, at which an absorbance is 0.4, is preferably 80 to 118 nm, more preferably 85 to 117 nm, and still more preferably 87 to 116 nm. In addition, it is preferable that λ3 exists in a range of 460 to 490 nm, it is more preferable to exist in a range of 465 to 485 nm, and it is still more preferable to exist in a range of 470 to 480 nm. In addition, it is preferable that λ4 exists in a range of 555 to 605 nm, it is more preferable to exist in a range of 560 to 600 nm, and it is still more preferable to exist in a range of 565 to 595 nm.

From the viewpoint of color separation property, the difference (λ3−λ1) between λ3 and λ1 is preferably 3 to 20 nm, more preferably 5 to 15 nm, and still more preferably 7 to 12 nm. In addition, from the viewpoint of color separation property, the difference (λ2-λ4) between λ2 and 4 is preferably 10 to 60 nm, more preferably 15 to 50 nm, and still more preferably 20 to 40 nm. In addition, from the viewpoint of color separation property, the difference (λmin−λ3) between λmin and λ3 is preferably 20 to 50 nm, more preferably 25 to 45 nm, and still more preferably 30 to 40 nm. In addition, from the viewpoint of color separation property, the difference (λ4−λmin) between λ4 and λmin is preferably 40 to 100 nm, more preferably 45 to 90 nm, and still more preferably 55 to 85 nm.

In the coloring composition according to the embodiment of the present invention, A⁴⁵⁰/A⁶²⁰, which is a ratio of an absorbance A⁴⁵⁰ to light having a wavelength of 450 nm and an absorbance A⁶²⁰ to light having a wavelength of 620 nm, is 1.08 to 2.05.

In the coloring composition according to the embodiment of the present invention, from the reason that it is easier to obtain more excellent brightness, A⁴⁵⁰/A^{min1}, which is a ratio of a minimum absorbance A^{min1} to light having a wavelength of 495 to 525 nm and the absorbance A⁴⁵⁰ to light having a wavelength of 450 nm, is preferably 10 to 30, more preferably 15 to 25, and still more preferably 13 to 17.

In the coloring composition according to the embodiment of the present invention, from the reason that it is easier to obtain more excellent brightness, A⁶²⁰/A^{min1}, which is a ratio of a minimum absorbance A^{min1} to light having a wavelength of 495 to 525 nm and the absorbance A⁶²⁰ to light having a wavelength of 620 nm, is preferably 5 to 15, more preferably 7.5 to 12.5, and still more preferably 8.25 to 12.25.

In a case where a cured film having a film thickness of 0.6 to 3.0 μm is formed, in the transmission spectrum to light having a wavelength range of 400 to 700 nm in a thickness direction of the film, the coloring composition according to the embodiment of the present invention has a peak value of transmittance in a wavelength range of 495 to 525 nm. In addition, the difference (λ^{T50L}−λ^{T50S}) between a wavelength (hereinafter, also referred to as λ^{T50L}) on the longer wavelength side than the wavelength of the peak value, at which the transmittance is 50% of the peak value, and a wavelength (hereinafter, also referred to as λ^{T50S}) on the shorter wavelength side than the wavelength of the peak value, at which the transmittance is 50% of the peak value, is preferably 65 to 90 nm, more preferably 70 to 85 nm, and still more preferably 75 to 80 nm.

In addition, the difference (λ^{Tmax}−λ^{T50S}) between the wavelength (hereinafter, also referred to as λ^{Tmax}) of the peak value of transmittance and the wavelength (λ^{T50S}) on the shorter wavelength side than the wavelength of the peak value, at which the transmittance is 50% of the peak value, is preferably 15 to 40 nm, more preferably 20 to 35 nm, and still more preferably 25 to 30 nm.

In addition, the difference (λ^{T50L}−λ^{Tmax}) between the wavelength (λ^{T50L}) on the longer wavelength side than the wavelength of the peak value, at which the transmittance is 50% of the peak value, and the wavelength (λ^{Tmax}) of the peak value of transmittance is preferably 35 to 60 nm, more preferably 40 to 55 nm, and still more preferably 45 to 50 nm.

In a case where a cured film having a film thickness of 0.6 to 3.0 μm is formed, it is preferable that, in a thickness direction of the film, the coloring composition according to the embodiment of the present invention has a maximum transmittance of 65% or more to light having a wavelength of 495 to 525 nm and has an average transmittance of 60% or more to light having a wavelength of 495 to 525 nm, and it is more preferable to have a maximum transmittance of 70% or more to light having a wavelength of 495 to 525 nm and have an average transmittance of 65% or more to light having a wavelength of 495 to 525 nm.

In addition, the transmittance to light having a wavelength of 450 nm is preferably 10% or less, more preferably 5% or less, and still more preferably 1% or less. In addition, the maximum transmittance to light having a wavelength of 400 to 450 nm is preferably 10% or less, more preferably 5% or less, and still more preferably 1% or less.

In addition, the transmittance to light having a wavelength of 620 nm is preferably 10% or less, more preferably 5% or less, and still more preferably 1% or less. In addition, the maximum transmittance to light having a wavelength of 600 to 625 nm is preferably 10% or less, more preferably 5% or less, and still more preferably 1% or less.

In addition, each transmittance to light having a wavelength of 480 nm and light having a wavelength of 570 nm is preferably 50% or less and more preferably 45% or less. In addition, each transmittance to light having a wavelength of 460 nm and light having a wavelength of 580 nm is preferably 20% or less and more preferably 15% or less.

In order to adjust the values such as the absorbance of the coloring composition within the above-described range, the values can be appropriately adjusted by changing the proportion of the at least one selected from Color Index Pigment Blue 15:3 or Color Index Pigment Blue 15:4, and Color Index Pigment Yellow 150, which are included in the colorant, the content thereof, the content of the colorant in the coloring composition, and the like.

The coloring composition according to the embodiment of the present invention can be preferably used as a coloring composition for forming a pixel of a color filter, and can be more preferably used as a coloring composition for forming a green pixel of a color filter.

The coloring composition according to the embodiment of the present invention can be preferably used as a coloring composition for a display device. More specifically, the coloring composition according to the embodiment of the present invention can be preferably used as a coloring composition for forming a pixel of a color filter for a display device, and can be more preferably used as a coloring composition for forming a green pixel of a color filter for a display device. The type of display device is not particularly limited, and examples thereof include a display device having an organic semiconductor element such as an organic electroluminescent display device as a light source.

In addition, the coloring composition according to the embodiment of the present invention can also be used as a coloring composition for a solid-state imaging element. More specifically, the coloring composition according to the embodiment of the present invention can be preferably used as a coloring composition for forming a pixel of a color filter for a solid-state imaging element, and can be more preferably used as a coloring composition for forming a green pixel of a color filter for a solid-state imaging element.

It is also preferable that the coloring composition according to the embodiment of the present invention is used for forming a cured film at a temperature of 150° C. or lower (preferably, a temperature of 120° C. or lower) throughout entire steps. In the present specification, forming a cured film at a temperature of 150° C. or lower throughout entire steps means that all steps of forming a cured film using the coloring composition are performed at a temperature of 150° C. or lower.

The thickness of the cured film and pixel formed by the coloring composition according to the embodiment of the present invention is preferably 0.5 to 3.0 μm. The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less.

In addition, the line width (pattern size) of the pixel formed by the coloring composition according to the embodiment of the present invention is preferably 2.0 to 10.0 μm. The upper limit is preferably 7.5 μm or less, more preferably 5.0 μm or less, and still more preferably 4.0 μm or less. The lower limit is preferably 2.25 μm or more, more preferably 2.5 μm or more, and still more preferably 2.75 μm or more.

Hereinafter, the coloring composition according to the embodiment of the present invention will be described in detail.

<<Colorant>>

The coloring composition according to the embodiment of the present invention contains a colorant. The colorant used in the coloring composition according to the embodiment of the present invention includes at least one selected from Color Index (C. I.) Pigment Blue 15:3 or C. I. Pigment Blue 15:4, and C. I. Pigment Yellow 150.

The colorant used in the coloring composition according to the embodiment of the present invention contains 35 to 55 parts by mass of C. I. Pigment Blue 15:3 and C. I. Pigment Blue 15:4 in total with respect to 100 parts by mass of C. I. Pigment Yellow 150. From the viewpoint of light resistance, the upper limit is preferably 52.5 parts by mass or less, more preferably 50 parts by mass or less, and still more preferably 47.5 parts by mass or less. From the viewpoint of color separation property, the lower limit is preferably 37.5 parts by mass or more and more preferably 40 parts by mass or more.

The colorant used in the coloring composition according to the embodiment of the present invention may be a colorant which includes C. I. Pigment Blue 15:3 and C. I. Pigment Blue 15:4, or may be a colorant only one of these. In addition, in a case where the colorant includes C. I. Pigment Blue 15:3 and C. I. Pigment Blue 15:4, the mass ratio of C. I. Pigment Blue 15:3 and C. I. Pigment Blue 15:4 is preferably 5 to 500 parts by mass of C. I. Pigment Blue 15:4, more preferably 25 to 250 parts by mass of C. I. Pigment Blue 15:4, and still more preferably 50 to 150 parts by mass of C. I. Pigment Blue 15:4 with respect to 100 parts by mass of C. I. Pigment Blue 15:3.

The total content of C. I. Pigment Blue 15:3, C. I. Pigment Blue 15:4, and C. I. Pigment Yellow 150 in the colorant is preferably 80 to 100 mass %, more preferably 85 to 100 mass %, still more preferably 90 to 100 mass %, even more preferably 95 to 100 mass %, and particularly preferably 99 to 100 mass %.

The colorant used in the coloring composition according to the embodiment of the present invention may contain a colorant (hereinafter, also referred to as other colorants) other than C. I. Pigment Blue 15:3, C. I. Pigment Blue 15:4, and C. I. Pigment Yellow 150. The content of the other colorants in the colorant is preferably less than 20 mass %, more preferably less than 15 mass %, still more preferably less than 10 mass %, even more preferably less than 5 mass %, and particularly preferably less than 1 mass %. It is particularly preferable that the colorant used in the coloring composition according to the embodiment of the present invention does not substantially contain other colorants. The case where the colorant used in the coloring composition according to the embodiment of the present invention does not substantially contain other colorants means that the content of other colorants in the colorant is less than 0.5 mass %, preferably less than 0.1 mass % and more preferably 0 mass %.

Examples of the other colorants include chromatic colorants such as a red colorant, a green colorant, a blue colorant, a yellow colorant, a violet colorant, and an orange colorant. The other colorants may be either a pigment or a dye. The pigment and the dye may be used in combination. In addition, the pigment may be either an inorganic pigment or an organic pigment. In addition, as the pigment, a material in which a part of an inorganic pigment or an organic-inorganic pigment is substituted with an organic chromophore can also be used. By substituting a part of an inorganic pigment or an organic-inorganic pigment with an organic chromophore, color tone design can be easily performed. Examples of the pigment include the following pigments:

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 231, 232 (methine-based), 233 (quinoline-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (azo-based), 296 (azo-based), and the like (all of which are red pigments);

C. I. Pigment Green 7, 10, 36, 37, 58, 59, 62, 63, and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:6, 16, 22, 29, 60, 64, 66, 79, 80, 87 (monoazo-based), 88 (methine-based), and the like (all of which are blue pigments).

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, and the like can also be used.

In addition, as the blue pigment, an aluminum phthalocyanine compound having a phosphorus atom can also be used. Specific examples thereof include the compounds described in paragraphs “0022” to “0030” of JP2012-247591A and paragraph “0047” of JP2011-157478A.

In addition, examples of the yellow pigment include compounds described in JP2017-201003A, compounds described in JP2017-197719A, compounds described in paragraphs “0011” to “0062” and “0137” to “0276” of JP2017-171912A, compounds described in paragraphs “0010” to “0062” and “0138” to “0295” of JP2017-171913A, compounds described in paragraphs “0011” to “0062” and “0139” to “0190” of JP2017-171914A, compounds described in paragraphs “0010” to “0065” and “0142” to “0222” of JP2017-171915A, quinophthalone compounds described in paragraphs “0011” to “0034” of JP2013-054339A, quinophthalone compounds described in paragraphs “0013” to “0058” of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in paragraph “0016” of JP6443711B, and quinophthalone compounds described in paragraphs “0047” and “0048” of JP6432077B.

As the red pigment, diketopyrrolopyrrole compounds described in JP2017-201384A, in which the structure has at least one substituted bromine atom, diketopyrrolopyrrole compounds described in paragraph “0016” to “0022” of JP6248838B, diketopyrrolopyrrole compounds described in WO2012/102399A, diketopyrrolopyrrole compounds described in WO2012/117965A, naphtholazo compounds described in JP2012-229344, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye. In addition, thiazole compounds described in JP2012-158649A, azo compounds described in JP2011-184493A, or azo compounds described in JP2011-145540A can also be preferably used. In addition, as yellow dyes, quinophthalone compounds described in paragraphs “0011” to “0034” of JP2013-054339A, quinophthalone compounds described in paragraphs “0013” to “0058” of JP2014-026228A, or the like can also be used.

The other colorants may be a coloring agent multimer. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. The weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, WO2016/031442A, or the like can also be used.

The content of the colorant in the total solid content of the coloring composition is preferably 20 mass % or more, more preferably 30 mass % or more, and still more preferably 40 mass % or more. The upper limit is preferably 80 mass % or less, more preferably 75 mass % or less, and still more preferably 70 mass % or less.

<<Polymerizable Compound>>

The coloring composition according to the embodiment of the present invention contains a polymerizable compound. Examples of the polymerizable compound include a compound having an ethylenically unsaturated bond-containing group. Examples of the ethylenically unsaturated bond-containing group include a vinyl group, a (meth)allyl group, and a (meth)acryloyl group. The polymerizable compound is preferably a compound (radical polymerizable compound) which can be polymerized by radicals.

Any chemical forms of a monomer, a prepolymer, an oligomer, or the like may be used as the polymerizable compound, but a monomer is preferable. The molecular weight of the polymerizable compound is preferably 100 to 3000. The upper limit is preferably 2000 or less and more preferably 1500 or less. The lower limit is preferably 150 or more and more preferably 250 or more.

From the viewpoint of temporal stability of the coloring composition, an ethylenically unsaturated bond-containing group value (hereinafter, referred to as a C═C value) of the polymerizable compound is preferably 2 to 14 mmol/g. The lower limit is preferably 3 mmol/g or more, more preferably 4 mmol/g or more, and still more preferably 5 mmol/g or more. The upper limit is preferably 12 mmol/g or less, more preferably 10 mmol/g or less, and still more preferably 8 mmol/g or less. The C═C value of the polymerizable compound is calculated by dividing the number of ethylenically unsaturated bond-containing groups included in one molecule of the polymerizable compound by the molecular weight of the polymerizable compound.

The polymerizable compound is preferably a compound including three or more ethylenically unsaturated bond-containing groups, and more preferably a compound including four or more ethylenically unsaturated bond-containing groups. According to this aspect, curing properties of the coloring composition by exposure are good. From the viewpoint of temporal stability of the coloring composition, the upper limit of the number of ethylenically unsaturated bond-containing groups is preferably 15 or less, more preferably 10 or less, and still more preferably 6 or less. In addition, as the polymerizable compound, a (meth)acrylate compound having 3 or more functional groups is preferable, a (meth)acrylate compound having 3 to 15 functional groups is more preferable, a (meth)acrylate compound having 3 to 10 functional groups is still more preferable, and a (meth)acrylate compound having 3 to 6 functional groups is particularly preferable.

It is also preferable that the polymerizable compound is a compound including an ethylenically unsaturated bond-containing group and an alkyleneoxy group. Since such a polymerizable compound has high flexibility and the ethylenically unsaturated bond-containing group is easily moved, the polymerizable compounds easily react with each other in a case of exposure and a cured film (pixel) having excellent adhesiveness to a support or the like can be formed. In addition, in a case where a hydroxyalkylphenone compound is used as the photopolymerization initiator, it is assumed that the polymerizable compound and the photopolymerization initiator are close to each other such that a radical can be generated in the vicinity of the polymerizable compound to allow the polymerizable compound to react more effectively, therefore easily forming a cured film (pixel) having more excellent adhesiveness and solvent resistance.

The number of alkyleneoxy groups included in one molecule of the polymerizable compound is preferably 3 or more and more preferably 4 or more. From the viewpoint of temporal stability of the coloring composition, the upper limit is preferably 20 or less.

In addition, from the viewpoint of compatibility with other components included in the coloring composition, a solubility parameter (SP) value of the compound including an ethylenically unsaturated bond-containing group and an alkyleneoxy group is preferably 9.0 to 11.0. The upper limit is preferably 10.75 or less and more preferably 10.5 or less. The lower limit is preferably 9.25 or more and more preferably 9.5 or more. In the present specification, the SP value is a calculated value based on Fedors method.

Examples of the compound having an ethylenically unsaturated bond-containing group and an alkyleneoxy group include a compound represented by Formula (M-1).

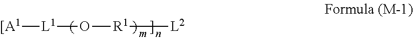

In the formula, A¹ represents an ethylenically unsaturated bond-containing group, L¹ represents a single bond or a divalent linking group, R¹ represents an alkylene group, m represents an integer of 1 to 30, n represents an integer of 3 or more, and L² represents an n-valent linking group.

Examples of the ethylenically unsaturated bond-containing group represented by A¹ include a vinyl group, a (meth)allyl group, and a (meth)acryloyl group, and a (meth)acryloyl group is preferable.

Examples of the divalent linking group represented by L¹ include an alkylene group, an arylene group, —O—, —CO—, —COO—, —OCO—, —NH—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10.

The number of carbon atoms in the alkylene group represented by R¹ is preferably 1 to 10, more preferably 1 to 5, still more preferably 1 to 3, particularly preferably 2 or 3, and most preferably 2. The alkylene group represented by R¹ is preferably linear or branched, and more preferably linear. Specific examples of the alkylene group represented by R¹ include an ethylene group and a linear or branched propylene group, and an ethylene group is preferable.

m represents an integer of 1 to 30, and is preferably an integer of 1 to 20, more preferably an integer of 1 to 10, and still more preferably an integer of 1 to 5.

n represents an integer of 3 or more, and is preferably an integer of 4 or more. The upper limit of n is preferably an integer of 15 or less, more preferably an integer of 10 or less, and still more preferably an integer of 6 or less.

Examples of the n-valent linking group represented by L² include an aliphatic hydrocarbon group, an aromatic hydrocarbon group, a heterocyclic group, a group consisting of a combination thereof, and a group of a combination of at least one selected from an aliphatic hydrocarbon group, an aromatic hydrocarbon group, and a heterocyclic group, and at least one selected from —O—, —CO—, —COO—, —OCO—, and —NH—. The number of carbon atoms in the aliphatic hydrocarbon group is preferably 1 to 30, more preferably 1 to 20, and still more preferably 1 to 15. The aliphatic hydrocarbon group may linear, branched, or cyclic, and is preferably linear or branched. The number of carbon atoms in the aromatic hydrocarbon group is preferably 6 to 30, more preferably 6 to 20, and still more preferably 6 to 10. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The n-valent linking group represented by L² is also preferably a group derived from a polyfunctional alcohol.

As the compound having an ethylenically unsaturated bond-containing group and an alkyleneoxy group, a compound represented by Formula (M-2) is more preferable.

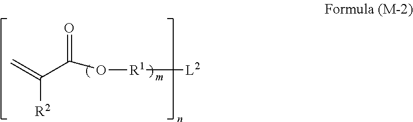

In the formula, R² represents a hydrogen atom or a methyl group, R¹ represents an alkylene group, m represents an integer of 1 to 30, n represents an integer of 3 or more, and L² represents an n-valent linking group. R¹, L², m, and n in Formula (M-2) have the same meaning as R¹, L², m, and n in Formula (M-1), and the preferred ranges are also the same.

Examples of a commercially available product of the compound having an ethylenically unsaturated bond-containing group and an alkyleneoxy group include KAYARAD T-1420(T) and RP-1040 (manufactured by Nippon Kayaku Co., Ltd.).

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), a compound having a structure in which the (meth)acryloyl group of these compounds is bonded through an ethylene glycol and/or a propylene glycol residue (for example, SR454 and SR499 which are commercially available from Sartomer), and the like can also be used. In addition, as the polymerizable compound, ARONIX M-402 (manufactured by TOAGOSET CO., LTD.; a mixture of dipentaerythritol hexaacrylate and dipentaerythritol pentaacrylate) can also be preferably used. In addition, as the polymerizable compound, trifunctional (meth)acrylate compounds such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate can also be preferably used. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, it is also preferable to use a polymerizable compound having an acid group. By using a polymerizable compound having an acid group, a coloring composition layer in an unexposed area is easily removed during development and the generation of the development residue can be suppressed. Examples of the acid group include a carboxyl group, a sulfo group, and a phosphoric acid group, and a carboxyl group is preferable. Examples of the polymerizable compound having an acid group include succinic acid-modified dipentaerythritol penta(meth)acrylate. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

As the polymerizable compound, it is also preferable to use a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

As the polymerizable compound, compounds described in JP2017-048367A, JP6057891B, JP6031807B, and JP2017-194662A, 8UH-1006 and 8UH-1012 (both of which are manufactured by Taisei Fine Chemical Co., Ltd.), Light Acrylate POB-A0 (manufactured by Kyoeisha Chemical Co., Ltd.), and the like can also be used.

The content of the polymerizable compound in the total solid content of the coloring composition is preferably 5.0 to 35 mass %. The upper limit is preferably 30 mass % or less and more preferably 25 mass % or less. The lower limit is preferably 7.5 mass % or more and more preferably 10 mass % or more.

<<Photopolymerization Initiator>>

The coloring composition according to the embodiment of the present invention contains a photopolymerization initiator. The photopolymerization initiator is not particularly limited, and can be appropriately selected from known photopolymerization initiators. For example, a compound having photosensitivity to light ray in a range from an ultraviolet range to a visible range is preferable. The photopolymerization initiator is preferably a photoradical polymerization initiator.

Examples of the photopolymerization initiator include halogenated hydrocarbon derivatives (such as a compound having a triazine skeleton and a compound having an oxadiazole skeleton), acylphosphine compounds such as acylphosphine oxide, a hexaaryl biimidazole compound, oxime compounds such as an oxime derivative, an organic peroxide, a thio compound, a ketone compound, an aromatic onium salt, a ketoxime ether compound, an aminoalkylphenone compound, a hydroxyalkylphenone compound, and a phenylglyoxylate compound. With regard to the specific examples of the photopolymerization initiator, reference can be made to paragraphs “0265” to “0268” of JP2013-029760A and JP6301489B, the contents of which are incorporated herein by reference. The photopolymerization initiator used in the present invention is preferably a photopolymerization initiator containing an oxime compound, and more preferably a photopolymerization initiator containing an oxime compound and a hydroxyalkylphenone compound.

Examples of the phenylglyoxylate compound include phenylglyoxylic acid methyl ester. Examples of a commercially available product thereof include Omnirad MBF (manufactured by IGM Resins B.V.) and Irgacure MBF (manufactured by BASF).

Examples of the aminoalkylphenone compound include the aminoalkylphenone compound described in JP1998-291969A (JP-H10-291969A). In addition, examples of a commercially available product of the aminoalkylphenone compound include Omnirad 907, Omnirad 369, Omnirad 369E, and Omnirad 379EG (all of which are manufactured by IGM Resins B.V), Irgacure 907, Irgacure 369, Irgacure 369E, and Irgacure 379EG (all of which are manufactured by BASF).

Examples of the acylphosphine compound include the acylphosphine compound described in JP4225898B. Specific examples thereof include bis(2,4,6-trimethylbenzoyl)-phenylphosphine oxide. Examples of a commercially available product of the acylphosphine compound include Omnirad 819 and Omnirad TPO (both of which are manufactured by IGM Resins B.V), Irgacure 819 and Irgacure TPO (both of which are manufactured by BASF).

Examples of the hydroxyalkylphenone compound include a compound represented by Formula (V).

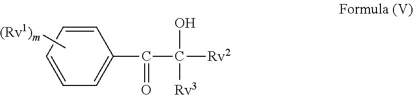

In the formula, Rv¹ represents a substituent, Rv² and Rv³ each independently represent a hydrogen atom or a substituent, Rv² and Rv³ may be bonded to each other to form a ring, and m represents an integer of 0 to 5.

Examples of the substituent represented by Rv¹ include an alkyl group (preferably an alkyl group having 1 to 10 carbon atoms) and an alkoxy group (preferably an alkoxy group having 1 to 10 carbon atoms). The alkyl group and alkoxy group are preferably linear or branched, and more preferably linear. The alkyl group and alkoxy group represented by Rv¹ may be unsubstituted or may have a substituent. Examples of the substituent include a hydroxy group and a group having a hydroxyalkylphenone structure. Examples of the group having a hydroxyalkylphenone structure include a group of a structure in which, in Formula (V), one hydrogen atom is removed from the benzene ring bonded with Rv¹ or from Rv¹.

Rv² and Rv³ each independently represent a hydrogen atom or a substituent. As the substituent, an alkyl group (preferably an alkyl group having 1 to 10 carbon atoms) is preferable. In addition, Rv² and Rv³ may be bonded to each other to form a ring (preferably a ring having 4 to 8 carbon atoms and more preferably an aliphatic ring having 4 to 8 carbon atoms). The alkyl group is preferably linear or branched, and more preferably linear.

Specific examples of the compound represented by Formula (V) include the following compounds.

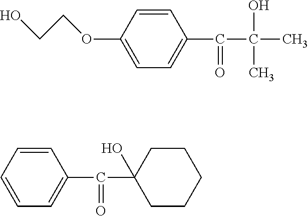 [SMILES: CC(C)(O)C(=O)c1ccc(OCCO)cc1 ; O=C(c1ccccc1)C1(O)CCCCC1]

Examples of a commercially available product of the hydroxyalkylphenone compound include Omnirad 184, Omnirad 1173, Omnirad 2959, and Omnirad 127 (all of which are manufactured by IGM Resins B.V), Irgacure 184, Irgacure 1173, Irgacure 2959, and Irgacure 127 (all of which are manufactured by BASF).

Examples of the oxime compound include the compounds described in JP2001-233842A, the compounds described in JP2000-080068A, the compounds described in JP2006-342166A, the compounds described in J. C. S. Perkin 11 (1979, pp. 1653-1660), the compounds described in J. C. S. Perkin 11 (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraphs “0025” to “0038” of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by Changzhou Tronly Chemical Co., Ltd.), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

The oxime compound is also preferably an oxime compound including a fluorine atom. The oxime compound including a fluorine atom is preferably a compound represented by Formula (OX-1).

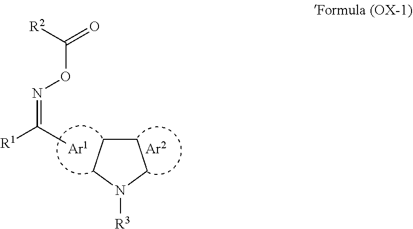

In Formula (OX-1), Ar¹ and Ar² each independently represent an aromatic hydrocarbon ring which may have a substituent, R¹ represents an aryl group having a group including a fluorine atom, and R² and R³ each independently represent an alkyl group or an aryl group.

Ar¹ and Ar² each independently represent an aromatic hydrocarbon ring which may have a substituent. The aromatic hydrocarbon ring may be a single ring or a fused ring.

The number of carbon atoms constituting the ring of the aromatic hydrocarbon ring is preferably 6 to 20, more preferably 6 to 15, and particularly preferably 6 to 10. The aromatic hydrocarbon ring is preferably a benzene ring or a naphthalene ring. Among these, it is preferable that at least one of Ar¹ or Ar² is a benzene ring, and it is more preferable that Ar¹ is a benzene ring. Ar² is preferably a benzene ring or a naphthalene ring and more preferably a naphthalene ring.

Example of the substituent which may be included in Ar¹ and Ar² include an alkyl group, an aryl group, a heterocyclic group, a nitro group, a cyano group, a halogen atom, —OR^{X1}, —SR^{X1}, —COR^{X1}, —COOR^{X1}, —OCOR^{X1}, —NR^{X1}R^{X2}, —NHCOR^{X1}, —CONR^{X1}R^{X2}, —NHCONR^{X1}R^{X2}, —NHCOOR^{X1}, —SO₂R^{X1}, —SO₂OR^{X1}, and —NHSO₂R^{X1}. R^{X1} and R^{X2} each independently represent a hydrogen atom, an alkyl group, an aryl group, or a heterocyclic group. Examples of the halogen atom include a fluorine atom, a chlorine atom, a bromine atom, and an iodine atom, and a fluorine atom is preferable. The number of carbon atoms in the alkyl group as the substituent and in the alkyl group represented by R^{X1} and R^{X2} is preferably 1 to 30. The alkyl group may be linear, branched, or cyclic, and is preferably linear or branched. In the alkyl group, a part or all of the hydrogen atoms may be substituted with halogen atoms (preferably fluorine atoms). In addition, in the alkyl group, a part or all of the hydrogen atoms may be substituted with the above-described substituents. The number of carbon atoms of the aryl group as the substituent and the aryl group represented by R^{X1} and R^{X2} is preferably 6 to 20, more preferably 6 to 15, and still more preferably 6 to 10. The aryl group may be a single ring or a fused ring. In addition, in the aryl group, a part or all of the hydrogen atoms may be substituted with the above-described substituents. The heterocyclic group as the substituent and the heterocyclic group represented by R^{X1} and R^{X2} are preferably a 5-membered ring or a 6-membered ring. The heterocyclic group may be a single ring or a fused ring. The number of carbon atoms constituting the heterocyclic group is preferably 3 to 30, more preferably 3 to 18, and more preferably 3 to 12. The number of heteroatoms constituting the heterocyclic group is preferably 1 to 3. The heteroatom constituting the heterocyclic group is preferably a nitrogen atom, an oxygen atom, or a sulfur atom. In addition, in the heterocyclic group, a part or all of the hydrogen atoms may be substituted with the above-described substituents.

The aromatic hydrocarbon ring represented by Ar¹ is preferably unsubstituted. The aromatic hydrocarbon ring represented by Ar² may be unsubstituted or may have a substituent. It is preferable to have a substituent. As the substituent, —COR^{X1} is preferable. R^{X1} is preferably an alkyl group, an aryl group, or a heterocyclic group, and more preferably an aryl group. The aryl group may have a substituent or may be unsubstituted. Examples of the substituent include an alkyl group having 1 to 10 carbon atoms.

R¹ represents an aryl group having a group including a fluorine atom. The number of carbon atoms in the aryl group is preferably 6 to 20, more preferably 6 to 15, and still more preferably 6 to 10. The group including a fluorine atom is preferably an alkyl group having a fluorine atom (hereinafter, also referred to as a fluorine-containing alkyl group) or a group including an alkyl group having a fluorine atom (hereinafter, also referred to as a fluorine-containing group). As the fluorine-containing group, at least one group selected from —OR^{F1}, —SR^{F1}, —COR^{F1}, —COOR^{F1}, —OCOR^{F1}, —NR^{F1}R^{F2}, —NHCOR^{F1}, —CONR^{F1}R^{F2}, —NHCONR^{F1}R^{F2}, —NHCOOR^{F1}, —SO₂R^{F1}, —SO₂OR^{F1}, and —NHSO₂R^{F1} is preferable. R^{F1} represents a fluorine-containing alkyl group, and R^{F2} represents a hydrogen atom, an alkyl group, a fluorine-containing alkyl group, an aryl group, or a heterocyclic group. The fluorine-containing group is preferably —OR^{F1}.

The number of carbon atoms in the alkyl group and in the fluorine-containing alkyl group is preferably 1 to 20, more preferably 1 to 15, still more preferably 1 to 10, and particularly preferably 1 to 4. The alkyl group and fluorine-containing alkyl group may be linear, branched, or cyclic, and are preferably linear or branched. The substitution rate of fluorine atoms in the fluorine-containing alkyl group is preferably 40% to 100%, more preferably 50% to 100%, and still more preferably 60% to 100%. The substitution rate of fluorine atoms refers to a ratio (%) of the number substituted with fluorine atoms to the total number of hydrogen atoms in the alkyl group.

The number of carbon atoms in the aryl group is preferably 6 to 20, more preferably 6 to 15, and still more preferably 6 to 10.

The heterocyclic group is preferably a 5-membered ring or a 6-membered ring. The heterocyclic group may be a single ring or a fused ring. The fused number is preferably 2 to 8, more preferably 2 to 6, still more preferably 3 to 5, and particularly preferably 3 or 4. The number of carbon atoms constituting the heterocyclic group is preferably 3 to 40, more preferably 3 to 30, and more preferably 3 to 20. The number of heteroatoms constituting the heterocyclic group is preferably 1 to 3. The heteroatom constituting the heterocyclic group is preferably a nitrogen atom, an oxygen atom, or a sulfur atom, and more preferably a nitrogen atom.

The group including a fluorine atom preferably has a terminal structure represented by Formula (1) or (2). * in the formula represents a bonding site.

*—CHF₂ (1)

*—CF₃ (2)

R² represents an alkyl group or an aryl group, and is preferably an alkyl group. The alkyl group and aryl group may be unsubstituted or may have a substituent. Examples of the substituent include the substituents described as the substituent which may be included in Ar¹ and Ar². The number of carbon atoms in the alkyl group is preferably 1 to 20, more preferably 1 to 15, still more preferably 1 to 10, and particularly preferably 1 to 4. The alkyl group may be linear, branched, or cyclic, and is preferably linear or branched. The number of carbon atoms in the aryl group is preferably 6 to 20, more preferably 6 to 15, and still more preferably 6 to 10.

R³ represents an alkyl group or an aryl group, and is preferably an alkyl group. The alkyl group and aryl group may be unsubstituted or may have a substituent. Examples of the substituent include the substituents described as the substituent which may be included in Ar¹ and Ar². The number of carbon atoms in the alkyl group represented by R³ is preferably 1 to 20, more preferably 1 to 15, and still more preferably 1 to 10. The alkyl group may be linear, branched, or cyclic, and is preferably linear or branched. The number of carbon atoms in the aryl group represented by R³ is preferably 6 to 20, more preferably 6 to 15, and still more preferably 6 to 10.

Specific examples of the oxime compound having a fluorine atom include compounds described in JP2010-262028A, Compounds 24 and 36 to 40 described in JP2014-500852A, and Compound (C-3) described in JP2013-164471A.

In addition, as the oxime compound, an oxime compound having a fluorene ring can also be used. Specific examples of the oxime compound having a fluorene ring include compounds described in JP2014-137466A. The content thereof is incorporated herein by reference.

In addition, as the oxime compound, an oxime compound having a benzofuran skeleton can also be used. Specific examples thereof include compounds OE-01 to OE-75 described in WO2015/036910A.

In addition, as the oxime compound, an oxime compound having a skeleton in which at least one benzene ring of a carbazole ring is a naphthalene ring can also be used. Specific examples of such an oxime compound include the compounds described in WO2013/083505A.

In addition, as the oxime compound, an oxime compound having a nitro group can also be used. It is preferable that the oxime compound having a nitro group is a dimer. Specific examples of the oxime compound having a nitro group include compounds described in paragraphs “0031” to “0047” of JP2013-114249A and paragraphs “0008” to “0012” and “0070” to “0079” of JP2014-137466A, and compounds described in paragraphs “0007” to 0025” of JP4223071B.

Specific examples of the oxime compound are shown below, but the present invention is not limited thereto.

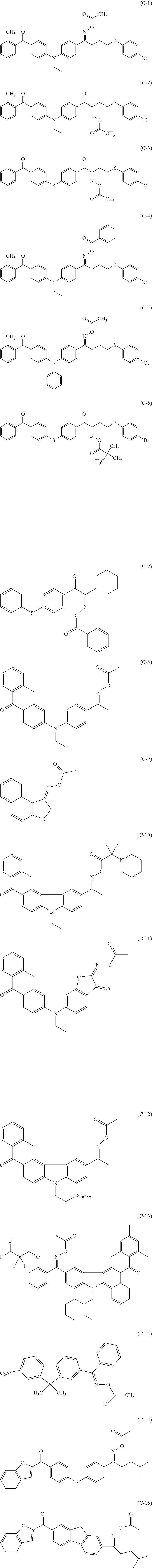

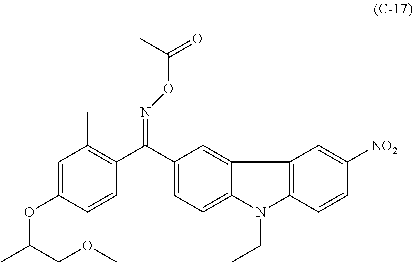 [SMILES: CCn1c2ccc(/C(=N\OC(C)=O)c3ccc(OC(C)COC)cc3C)cc2c2cc([N+](=O)[O-])ccc21]

In the present invention, as the photopolymerization initiator, it is preferable that a photopolymerization initiator A1 having a light absorption coefficient of 1.0×10³ mL/gcm or more at a wavelength of 365 nm in methanol, and a photopolymerization initiator A2 having a light absorption coefficient of 1.0×10² mL/gcm or less at a wavelength of 365 nm in methanol and having a light absorption coefficient of 1.0×10³ mL/gem or more at a wavelength of 254 nm in methanol are used in combination. According to this aspect, the coloring composition is easily cured sufficiently by exposure, high flatness is obtained in low-temperature process (for example, at a temperature of 150° C. or lower, preferably a temperature of 120° C. or lower, throughout entire steps), and a pixel having excellent characteristics such as solvent resistance can be formed. As the photopolymerization initiator A1 and the photopolymerization initiator A2, compounds having the above-described light absorption coefficient are preferably selected and used from the above-described compounds.

In the present invention, the light absorption coefficient of a photopolymerization initiator at the above-described wavelength is a value measured as follows. That is, the light absorption coefficient is obtained by preparing a measurement solution by dissolving the photopolymerization initiator in methanol, and measuring absorbance of the measurement solution. Specifically, the measurement solution is put into a glass cell having a width of 1 cm, absorbance is measured using a UV-Vis-NIR spectrometer (Cary 5000) manufactured by Agilent Technologies Inc., and the light absorption coefficient (mL/gcm) at a wavelength of 365 nm and a wavelength of 254 nm is obtained by applying the following expression.

$$ɛ = \frac{A}{cl} \qquad Expression 1$$

In the expression, ε represents a light absorption coefficient (mL/gcm), A represents an absorbance, c represents a concentration (g/mL) of the photopolymerization initiator, and 1 represents an optical path length (cm).

The light absorption coefficient of the photopolymerization initiator A1 at a wavelength of 365 nm in methanol is 1.0×10³ mL/gcm or more, preferably 1.0×10⁴ mL/gcm or more, more preferably 1.1×10⁴ mL/gcm or more, still more preferably 1.2×10⁴ to 1.0×10⁵ mL/gcm, even more preferably 1.3×10⁴ to 5.0×10⁴ mL/gcm, and particularly preferably 1.5×10⁴ to 3.0×10⁴ mL/gcm.

In addition, the light absorption coefficient of the photopolymerization initiator A1 at a wavelength of 254 nm in methanol is preferably 1.0×10⁴ to 1.0×10⁵ mL/gcm, more preferably 1.5×10⁴ to 9.5×10⁴ mL/gcm, and still more preferably 3.0×10⁴ to 8.0×10⁴ mL/gcm.

As the photopolymerization initiator A1, an oxime compound, an aminoalkylphenone compound, or an acylphosphine compound is preferable, an oxime compound or an acylphosphine compound is more preferable, an oxime compound is still more preferable, and from the viewpoint of compatibility with other components included in the composition, an oxime compound including a fluorine atom is particularly preferable. As the oxime compound including a fluorine atom, the above-described compound represented by Formula (OX-1) is preferable. Specific examples of the photopolymerization initiator A1 include 1,2-octanedione, 1-[4-(phenylthio)-,2-(O-benzoyloxime)] (as a commercially available product, for example, Irgacure OXE01 manufactured by BASF), ethanone, 1-[9-ethyl-6-(2-methylbenzoyl)-9H-carbazol-3-yl]-, 1-(0-acetyloxime) (as a commercially available product, for example, Irgacure OXE02 manufactured by BASF), and (C-13), (C-14), and (C-17), which are shown in the specific examples of the above-described oxime compound.

The light absorption coefficient of the photopolymerization initiator A2 at a wavelength of 365 nm in methanol is 1.0×10² mL/gcm or less, preferably 10 to 1.0×10² mL/gcm, and more preferably 20 to 1.0×10² mL/gcm. In addition, the difference between the light absorption coefficient of the photopolymerization initiator A1 at a wavelength of 365 nm in methanol and the light absorption coefficient of the photopolymerization initiator A2 at a wavelength of 365 nm in methanol is 9.0×10² mL/gcm or more, preferably 1.0×10³ mL/gcm or more, more preferably 5.0×10³ to 3.0×10⁴ mL/gcm, and still more preferably 1.0×10⁴ to 2.0×10⁴ mL/gcm. In addition, the light absorption coefficient of the photopolymerization initiator A2 at a wavelength of 254 nm in methanol is 1.0×10³ mL/gcm or more, preferably 1.0×10³ to 1.0×10⁶ mL/gcm, and more preferably 5.0×10³ to 1.0×10⁵ mL/gcm.

As the photopolymerization initiator A2, a hydroxyalkylphenone compound, a phenylglyoxylate compound, an aminoalkylphenone compound, or an acylphosphine compound is preferable, a hydroxyalkylphenone compound or a phenylglyoxylate compound is more preferable, and a hydroxyalkylphenone compound is still more preferable. In addition, as the hydroxyalkylphenone compound, the above-described compound represented by Formula (V) is preferable. Specific examples of the photopolymerization initiator A2 include 1-hydroxy-cyclohexyl-phenyl-ketone and 1-[4-(2-hydroxyethoxy)-phenyl]-2-hydroxy-2-methyl-1-propan-1-one.

As a combination of the photopolymerization initiator A1 and the photopolymerization initiator A2, a combination in which the photopolymerization initiator A1 is an oxime compound and the photopolymerization initiator A2 is a hydroxyalkylphenone compound is preferable, a combination in which the photopolymerization initiator A1 is an oxime compound and the photopolymerization initiator A2 is the compound represented by Formula (V) is more preferable, and a combination in which the photopolymerization initiator A1 is an oxime compound including a fluorine atom and the photopolymerization initiator A2 is the compound represented by Formula (V) is particularly preferable.

The content of the photopolymerization initiator in the total solid content of the coloring composition is preferably 3 to 25 mass %. The lower limit is preferably 5 mass % or more, more preferably 7.5 mass % or more, still more preferably 8 mass % or more, even more preferably 9 mass % or more, and particularly preferably 10 mass % or more. The upper limit is preferably 20 mass % or less, more preferably 17.5 mass % or less, and still more preferably 15 mass % or less. The photopolymerization initiator may be used singly or in combination of two or more kinds thereof. In a case where two or more kinds thereof are used in combination, the total content thereof is preferably within the above-described range.

In addition, in the coloring composition according to the embodiment of the present invention, in terms of mass %, the ratio (M/I) of a content M of the polymerizable compound in the total solid content and a content I of the photopolymerization initiator in the total solid content is preferably 20 or less. The upper limit of the above-described ratio is preferably 10 or less, more preferably 5 or less, still more preferably 3 or less, and particularly preferably 2 or less. The lower limit of the above-described ratio is preferably 0.1 or more and more preferably 0.5 or more.

In the coloring composition according to the embodiment of the present invention, in a case where the above-described oxime compound is used as the photopolymerization initiator, the content of the oxime compound in the total solid content of the coloring composition is preferably 3 to 25 mass %. The lower limit is preferably 5 mass % or more, more preferably 7.5 mass % or more, still more preferably 8 mass % or more, even more preferably 9 mass % or more, and particularly preferably 10 mass % or more. The upper limit is preferably 20 mass % or less, more preferably 17.5 mass % or less, and still more preferably 15 mass % or less. In a case where the content of the oxime compound is within the above-described range, adhesiveness of a cured film after development to the support can be improved. The oxime compound may be used singly or in combination of two or more kinds thereof. In a case where two or more kinds thereof are used in combination, the total content thereof is preferably within the above-described range.

In addition, in the coloring composition according to the embodiment of the present invention, in terms of mass %, the ratio (M/I_{O}) of the content M of the polymerizable compound in the total solid content and a content I_{O} of the oxime compound in the total solid content is preferably 20 or less. The upper limit of the above-described ratio is preferably 10 or less, more preferably 5 or less, still more preferably 3 or less, and particularly preferably 2 or less. The lower limit of the above-described ratio is preferably 0.1 or more and more preferably 0.5 or more.

In the coloring composition according to the embodiment of the present invention, in a case where the above-described photopolymerization initiator A1 is used as the photopolymerization initiator, the content of the photopolymerization initiator A1 in the total solid content of the coloring composition is preferably 3 to 25 mass %. The lower limit is preferably 5 mass % or more, more preferably 7.5 mass % or more, still more preferably 8 mass % or more, even more preferably 9 mass % or more, and particularly preferably 10 mass % or more. The upper limit is preferably 20 mass % or less, more preferably 17.5 mass % or less, and still more preferably 15 mass % or less. In a case where the content of the photopolymerization initiator A1 is within the above-described range, adhesiveness of the cured film after development to the support can be improved.

In the coloring composition according to the embodiment of the present invention, in terms of mass %, the ratio (M/I_{A1}) of the content M of the polymerizable compound in the total solid content and a content I_{A1} of the photopolymerization initiator A1 in the total solid content is preferably 20 or less. The upper limit of the above-described ratio is preferably 10 or less, more preferably 5 or less, still more preferably 3 or less, and particularly preferably 2 or less. The lower limit of the above-described ratio is preferably 0.1 or more and more preferably 0.5 or more.

In the coloring composition according to the embodiment of the present invention, in a case where the above-described photopolymerization initiator A2 is used as the photopolymerization initiator, the content of the photopolymerization initiator A2 in the total solid content of the coloring composition is preferably 0.1 to 10.0 mass %. The lower limit is preferably 0.5 mass % or more, more preferably 1.0 mass % or more, and still more preferably 1.5 mass % or more. The upper limit is preferably 9.0 mass % or less, more preferably 8.0 mass % or less, and still more preferably 7.0 mass % or less. In a case where the content of the photopolymerization initiator A2 is within the above-described range, solvent resistance of the cured film after development can be improved.

In the coloring composition according to the embodiment of the present invention, in a case where the above-described photopolymerization initiator A1 and the above-described photopolymerization initiator A2 are used as the photopolymerization initiator, it is preferable that the coloring composition according to the embodiment of the present invention contains 50 to 200 parts by mass of the photopolymerization initiator A2 with respect to 100 parts by mass of the photopolymerization initiator A1. The upper limit is preferably 175 parts by mass or less and more preferably 150 parts by mass or less. The lower limit is preferably 60 parts by mass or more and more preferably 70 parts by mass or more. According to this aspect, a cured film having excellent characteristics such as solvent resistance can be formed by low-temperature process (for example, process at a temperature of 150° C. or lower, preferably a temperature of 120° C. or lower, throughout entire steps). In a case where two or more kinds of the photopolymerization initiators A1 and two or more kinds of the photopolymerization initiators A2 are used in combination, it is preferable that the total content of each satisfies the above-described requirements.

In the coloring composition according to the embodiment of the present invention, in a case where the above-described photopolymerization initiator A1 and the above-described photopolymerization initiator A2 are used as the photopolymerization initiator, the total content of the photopolymerization initiator A1 and the photopolymerization initiator A2 in the total solid content of the coloring composition is preferably 3.1 to 25 mass %. The lower limit is preferably 3.1 mass % or more, preferably 5 mass % or more, more preferably 7.5 mass % or more, still more preferably 8 mass % or more, even more preferably 9 mass % or more, and particularly preferably 10 mass % or more. The upper limit is preferably 20 mass % or less, more preferably 17.5 mass % or less, and still more preferably 15 mass % or less.

The coloring composition according to the embodiment of the present invention may contain a photopolymerization initiator (hereinafter, also referred to as other photopolymerization initiators) other than the photopolymerization initiator A1 and the photopolymerization initiator A2 as the photopolymerization initiator, but it is preferable that the coloring composition according to the embodiment of the present invention does not substantially contain other photopolymerization initiators. The case where the coloring composition according to the embodiment of the present invention does not substantially contain other photopolymerization initiators means that the content of other photopolymerization initiators is 1 part by mass or less, more preferably 0.5 parts by mass or less, still more preferably 0.1 parts by mass or less, and even more preferably 0 parts by mass with respect to 100 parts by mass of the total amount of the photopolymerization initiator A1 and the photopolymerization initiator A2.

<<Resin>>

It is preferable that the coloring composition according to the embodiment of the present invention includes a resin. The resin is blended in, for example, an application for dispersing pigments (C. I. Pigment Blue 15:3, C. I. Pigment Blue 15:4, C. I. Pigment Yellow 150, and the like) in the coloring composition or an application as a binder. A resin which is mainly used for dispersing pigments in the coloring composition is also referred to as a dispersant. However, such applications of the resin are merely exemplary, and the resin can also be used for other purposes in addition to such applications.

The weight-average molecular weight (Mw) of the resin is preferably 2000 to 2000000. The upper limit is preferably 1000000 or less and more preferably 500000 or less. The lower limit is preferably 3000 or more, more preferably 4000 or more, and still more preferably 5000 or more.

Examples of the resin include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide-imide resin, a polyolefin resin, a cyclic olefin resin, a polyester resin, a styrene resin, and a siloxane resin. In addition, resins described in paragraphs “0041” to “0060” of JP2017-206689A, resins described in paragraphs “0022” to “0071” of JP2018-010856A, resins described in JP2017-057265A, resins described in JP2017-032685A, resins described in JP2017-075248A, and resins described in JP2017-066240A can also be used.

The resin used in the present invention may have an acid group. Examples of the acid group include a carboxyl group, a phosphoric acid group, a sulfo group, and a phenolic hydroxy group. Among these acid groups, one kind may be used alone, or two or more kinds may be used in combination. The resin having an acid group preferably includes a repeating unit having an acid group in the side chain. The resin having an acid group can also be used as an alkali-soluble resin or a dispersant.

The acid value of the resin having an acid group is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, particularly preferably 150 mgKOH/g or less, and most preferably 120 mgKOH/g or less.

The resin having an acid group may have a repeating unit derived from a maleimide compound. Examples of the maleimide compound include N-alkylmaleimide and N-arylmaleimide. Examples of the repeating unit derived from a maleimide compound include a repeating unit represented by Formula (C-mi).

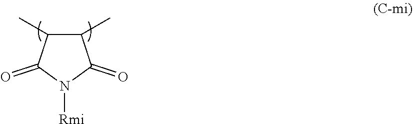

In Formula (C-mi), Rmi represents an alkyl group or an aryl group. The number of carbon atoms in the alkyl group is preferably 1 to 20. The alkyl group may be linear, branched, or cyclic. The number of carbon atoms in the aryl group is preferably 6 to 20, more preferably 6 to 15, and still more preferably 6 to 10. Rmi is preferably an aryl group.

As the resin having an acid group, a resin including a repeating unit derived from a compound represented by Formula (ED1) and/or a compound represented by Formula (ED2) (hereinafter, these compounds will also be referred to as an “ether dimer”) is also preferable.

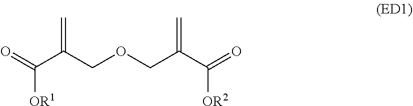

In Formula (ED1), R¹ and R² each independently represent a hydrogen atom or a hydrocarbon group having 1 to 25 carbon atoms, which may have a substituent.

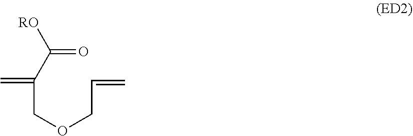

In Formula (ED2), R represents a hydrogen atom or an organic group having 1 to 30 carbon atoms. With regard to details of Formula (ED2), reference can be made to the description in JP2010-168539A, the contents of which are incorporated herein by reference. Specific examples of the ether dimer can be found in paragraph “0317” of JP2013-029760A, the contents of which are incorporated herein by reference.

Examples of the resin including a repeating unit derived from an ether dimer include resins having the following structures. In the following structural formulae, Me represents a methyl group.

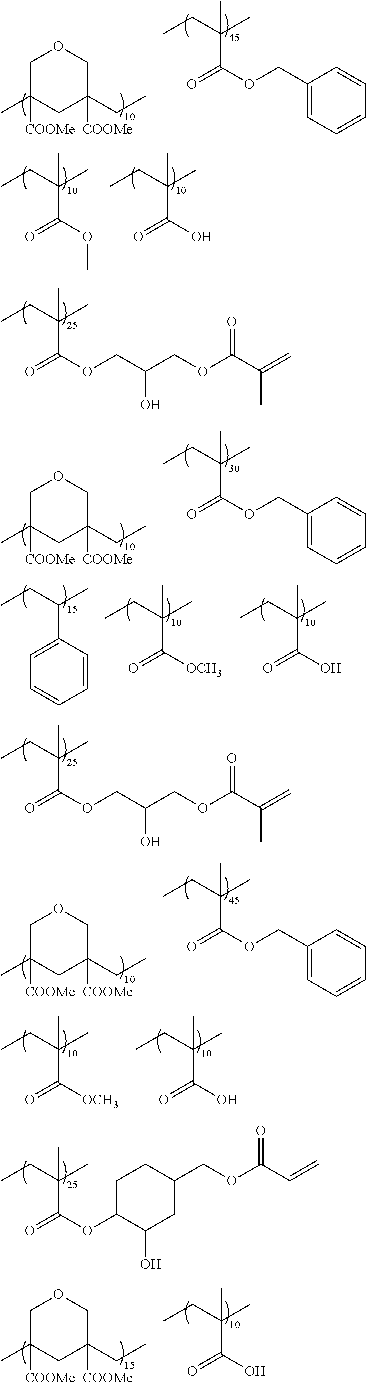

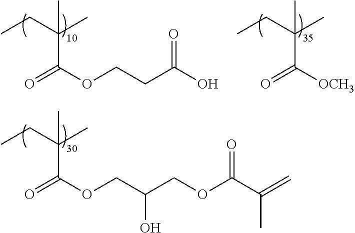

The resin used in the present invention may have a polymerizable group Examples of the polymerizable group include ethylenically unsaturated bond-containing groups such as a vinyl group, a (meth)allyl group, and a (meth)acryloyl group. Examples of a commercially available product of the resin having a polymerizable group include Dianal NR Series (manufactured by Mitsubishi Rayon Co., Ltd.), Photomer 6173 (polyurethane acrylate oligomer containing carboxyl group, manufactured by Diamond Shamrock Corp.), Viscoat R-264 and KS Resist 106 (both of which are manufactured by Osaka Organic Chemical Industry Ltd.), Cyclomer P series (for example, ACA230AA) and Placcel CF 200 series (all of which are manufactured by Daicel Corporation), Ebecryl 3800 (manufactured by Daicel UCB Company, Ltd.), Acrycure RD-F8 (manufactured by Nippon Shokubai Co., Ltd.), and DP-1305 (manufactured by Fuji Fine Chemicals).

The resin used in the present invention preferably contains a resin b1 which includes a repeating unit derived from a compound represented by Formula (I). By using the resin b1, it is easy to form a cured film having excellent curing properties at a low temperature and further having excellent spectral characteristics.

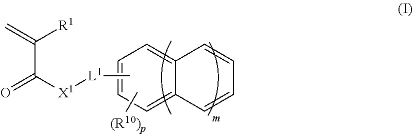

X¹ represents 0 or NH, and is preferably 0.

R¹ represents a hydrogen atom or a methyl group.

L¹ represents a divalent linking group. Examples of the divalent linking group include a hydrocarbon group, a heterocyclic group, —NH—, —SO—, SO₂—, —CO—, —O—, —COO—, —OCO—, —S—, and a group formed by a combination of two or more of these groups. Examples of the hydrocarbon group include an alkyl group and an aryl group. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The hydrocarbon group and heterocyclic group may have a substituent. Examples of the substituent include an alkyl group, an aryl group, a hydroxy group, and a halogen atom.

R¹⁰ represents a substituent. Examples of the substituent represented by R¹⁰ include the substituent T shown below, and the substituent represented by R¹⁰ is preferably a hydrocarbon group and more preferably an alkyl group which may have an aryl group as a substituent.

m represents an integer of 0 to 2, and is preferably 0 or 1 and more preferably 0.

p represents an integer of 0 or more, preferably 0 to 4, more preferably 0 to 3, still more preferably 0 to 2, even more preferably 0 or 1, and particularly preferably 1.

(Substituent T)

Examples of a substituent T include a halogen atom, a cyano group, a nitro group, a hydrocarbon group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, a hydrocarbon group, or a heterocyclic group. Rt¹ and Rt² may be bonded to each other to form a ring.

Examples of the halogen atom include a fluorine atom, a chlorine atom, a bromine atom, and an iodine atom.

Examples of the hydrocarbon group include an alkyl group, an alkenyl group, an alkynyl group, and an aryl group. The number of carbon atoms in the alkyl group is preferably 1 to 30, more preferably 1 to 15, and still more preferably 1 to 8. The alkyl group may be linear, branched, or cyclic, and is preferably linear or branched and more preferably branched.

The number of carbon atoms in the alkenyl group is preferably 2 to 30, more preferably 2 to 12, and particularly preferably 2 to 8. The alkenyl group may be linear, branched, or cyclic, and is preferably linear or branched.

The number of carbon atoms of the alkynyl group is preferably 2 to 30 and more preferably 2 to 25. The alkynyl group may be linear, branched, or cyclic, and is preferably linear or branched.

The number of carbon atoms in the aryl group is preferably 6 to 30, more preferably 6 to 20, and still more preferably 6 to 12.

The heterocyclic group may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and the heterocyclic group may have a substituent or may be unsubstituted. Examples of the substituent include the substituents described in the substituent T.

The compound represented by Formula (I) is preferably a compound represented by Formula (I-1).

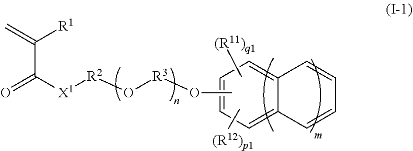

X¹ represents O or NH, and is preferably O.
R¹ represents a hydrogen atom or a methyl group.
R², R³, and R¹¹ each independently represent a hydrocarbon group.

The hydrocarbon group represented by R2 and R³ is preferably an alkylene group or an arylene group, and more preferably an alkylene group. The number of carbon atoms in the alkylene group is preferably 1 to 10, more preferably 1 to 5, still more preferably 1 to 3, and particularly preferably 2 or 3. The hydrocarbon group represented by R¹¹ is preferably an alkyl group which may have an aryl group as a substituent, and more preferably an alkyl group having an aryl group as a substituent. The number of carbon atoms in the alkyl group is preferably 1 to 20, more preferably 1 to 10, and still more preferably 1 to 5. The number of carbon atoms in the alkyl group in a case where the alkyl group has an aryl group as a substituent means the number of carbon atoms in an alkyl moiety.

R¹² represents a substituent. Examples of the substituent represented by R¹² include the above-described substituent T.

n represents an integer of 0 to 15, and is preferably an integer of 0 or 5, more preferably an integer of 0 to 4, and still more preferably an integer of 0 to 3.

m represents an integer of 0 to 2, preferably 0 or 1 and more preferably 0.

p1 represents an integer of 0 or more, preferably 0 to 4, more preferably 0 to 3, still more preferably 0 to 2, even more preferably 0 or 1, and particularly preferably 0.

q1 represents an integer of 1 or more, preferably 1 to 4, more preferably 1 to 3, still more preferably 1 to 2, and particularly preferably 1.

The compound represented by Formula (I) is preferably a compound represented by Formula (III).

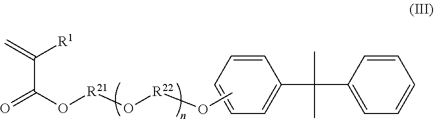

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (I) include ethylene oxide- or propylene oxide-modified (meth)acrylate of para-cumylphenol. Examples of a commercially available product thereof include ARONIX M-110 (manufactured by TOAGOSEI CO., LTD.).

In the resin b1, the proportion of the repeating unit derived from the compound represented by Formula (I) (preferably, Formula (III)) in all repeating units is preferably 1 to 99 mol %. The lower limit is more preferably 3 mol % or more and still more preferably 5 mol % or more. The upper limit is more preferably 95 mol % or less and still more preferably 90 mol % or less.

The resin b1 may further contain a repeating unit other than the repeating unit derived from the compound represented by Formula (I). For example, the resin b1 can contain a repeating unit derived from (meth)acrylate, and preferably contains a repeating unit derived from alkyl (meth)acrylate. The number of carbon atoms in an alkyl moiety of the alkyl (meth)acrylate is preferably 3 to 10, more preferably 3 to 8, and still more preferably 3 to 6.

Preferred specific examples of the alkyl (meth)acrylate include n-butyl (meth)acrylate. In addition, it is also preferable that the resin b1 contains a repeating unit having an acid group.

The coloring composition according to the embodiment of the present invention can contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group in the acidic dispersant (acidic resin) is preferably a carboxyl group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

Examples of the dispersant include polymer dispersants (for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate), polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant acts to prevent reaggregation by absorbing on a surface of particles such as pigments. Therefore, examples of a preferred structure of the polymer dispersant include a terminal-modified polymer, a graft polymer, and a block polymer, each of which has an anchor site for adsorbing on the surface of particles such as pigments. In addition, dispersants described in paragraphs “0028” to “0124” of JP2011-070156A or dispersants described in JP2007-277514A are preferably used.

In the present invention, a graft copolymer can also be used as the dispersant. With regard to details of the graft copolymer, reference can be made to the description in paragraphs “0131” to 0160 of JP2012-137564A, the contents of which are incorporated herein by reference. In addition, in the present invention, as the dispersant, an oligoimine copolymer including a nitrogen atom at at least one of a main chain or a side chain can also be used.

With regard to the oligoimine copolymer, reference can be made to the description in paragraphs “0102” to “0174” of JP2012-255128A, the contents of which are incorporated herein by reference.

A commercially available product is also available as the dispersant, and specific examples thereof include DISPERBYK series (for example, DISPERBYK-111, 2001, and the like) manufactured by BYK Chemie, Solsperse series (for example, Solsperse 20000, 76500, and the like) manufactured by Lubrizol Corporation, and AJISPER series manufactured by Ajinomoto Fine-Techno Co., Inc. In addition, products described in paragraph “0129” of JP2012-137564A and products described in paragraph “0235” of JP2017-194662A can also be used as the dispersant.

The content of the resin in the total solid content of the coloring composition is preferably 5 to 50 mass %. The upper limit is preferably 40 mass % or less and more preferably 30 mass % or less. The lower limit is preferably 7.5 mass % or more and more preferably 10 mass % or more.

In addition, the content of the resin is preferably 25 to 500 parts by mass with respect to 100 parts by mass of the polymerizable compound. The upper limit is preferably 250 parts by mass or less and more preferably 150 parts by mass or less. The lower limit is preferably 50 parts by mass or more and more preferably 75 parts by mass or more.

In addition, the content of the above-described resin b1 in the total amount of resins included in the coloring composition according to the embodiment of the present invention is preferably 0.1 to 100 mass % and more preferably 5 to 100 mass %. The upper limit may be 90 mass % or less, 80 mass % or less, or 70 mass % or less.

In addition, the content of the above-described resin b1 in the total solid content of the coloring composition is preferably 5 to 50 mass %. The upper limit is preferably 40 mass % or less and more preferably 30 mass % or less. The lower limit is preferably 10 mass % or more and more preferably 12.5 mass % or more.

<<Furyl group-containing Compound>>

The coloring composition according to the embodiment of the present invention preferably contains a compound (hereinafter, also referred to as a furyl group-containing compound) including a furyl group. According to this aspect, curing properties at low temperature are excellent.

The structure of the furyl group-containing compound is not particularly limited as long as the compound includes a furyl group (group obtained by removing one hydrogen atom from furan). As the furyl group-containing compound, compounds described in paragraphs “0049” to “0089” of JP2017-194662A can be used. In addition, compounds described in JP2000-233581A, JP1994-271558A, JP1994-293830A, JP1996-239421A, JP1998-508655A, JP2000-001529A, JP2003-183348A, JP2006-193628A, JP2007-186684A, JP2010-265377A, JP2011-170069A, and the like can also be used.

The furyl group-containing compound may be a monomer or a polymer. From the reason that it is easy to improve durability of a film to be obtained, a polymer is preferable. In a case of a polymer, the weight-average molecular weight thereof is preferably 2000 to 70000. The upper limit is preferably 60000 or less and more preferably 50000 or less. The lower limit is preferably 3000 or more, more preferably 4000 or more, and still more preferably 5000 or more. In a case of a monomer, the molecular weight is preferably less than 2000, more preferably 1800 or less, and still more preferably 1500 or less. The lower limit is preferably 100 or more, more preferably 150 or more, and still more preferably 175 or more. The polymer-type furyl group-containing compound is also a component corresponding to the resin in the coloring composition according to the embodiment of the present invention. In addition, the furyl group-containing compound having a polymerizable group is also a component corresponding to the polymerizable compound in the coloring composition according to the embodiment of the present invention.

Examples of the monomer-type furyl group-containing compound (hereinafter, also referred to as a furyl group-containing monomer) include a compound represented by Formula (fur-1).

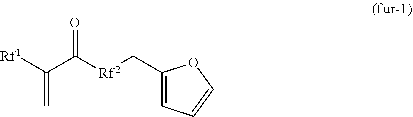

In the formula, Rf¹ represents a hydrogen atom or a methyl group, and Rf² represents a divalent linking group.

Examples of the divalent linking group represented by Rf² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

The furyl group-containing monomer is preferably a compound represented by Formula (fur-1-1).

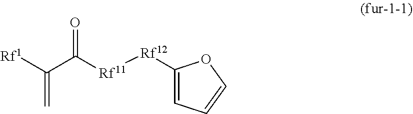

In the formula, Rf¹ represents a hydrogen atom or a methyl group, Rf¹¹ represents —O— or —NH—, and Rf¹² represents a single bond or a divalent linking group. Examples of the divalent linking group represented by Rf¹² include an alkylene group, an arylene group, —O—, —CO—, —COO—, —OCO—, —NH—, —S, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

Specific examples of the furyl group-containing monomer include compounds having the following structures. In the structural formulae, Rf¹ represents a hydrogen atom or a methyl group.

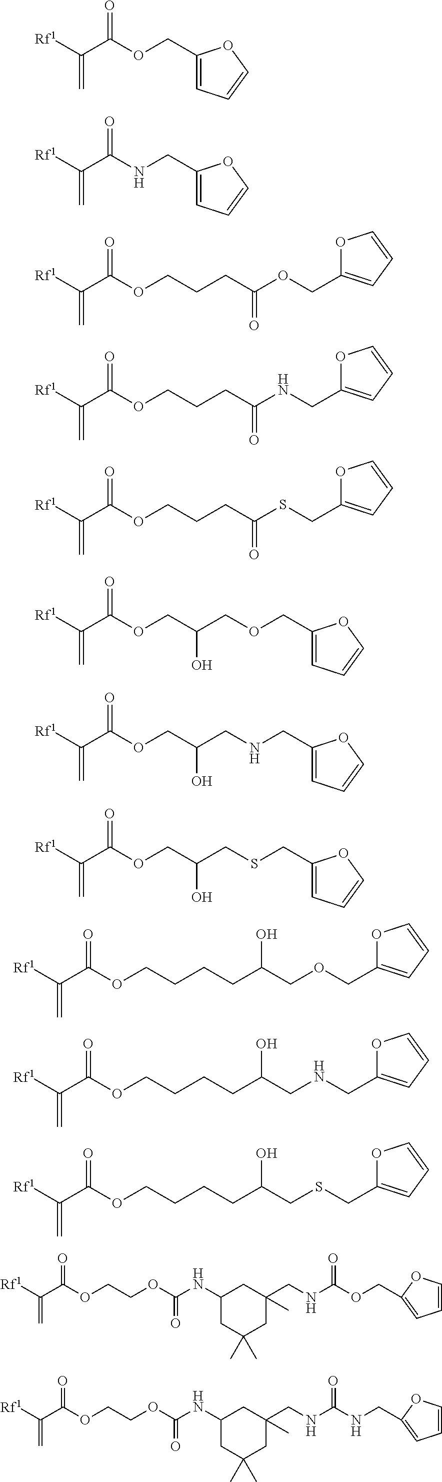

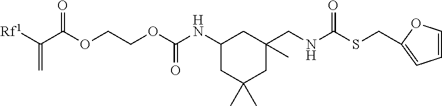

As the polymer-type furyl group-containing compound (hereinafter, also referred to as a furyl group-containing polymer), a resin including a repeating unit including a furyl group is preferable, and a resin including a repeating unit derived from the compound represented by Formula (fur-1) is more preferable. In the furyl group-containing polymer, the proportion of the repeating unit including a furyl group in all repeating units is preferably 30 to 70 mass %. The lower limit is preferably 35 mass % or more and more preferably 40 mass % or more. The upper limit is preferably 65 mass % or less and more preferably 60 mass % or less. The concentration of the furyl group in the furyl group-containing polymer is preferably 0.5 to 6.0 mmol and more preferably 1.0 to 4.0 mmol per 1 g of the furyl group-containing polymer. In a case where the concentration of the furyl group is 0.5 mmol or more, preferably 1.0 mmol or more, it is easy to form a cured film having more excellent solvent resistance and the like. In a case where the concentration of the furyl group is 6.0 mmol or less, preferably 4.0 mmol or less, the temporal stability of the coloring composition is good.

The furyl group-containing polymer may include a repeating unit having an acid group and/or a repeating unit having a polymerizable group, in addition to the repeating unit having a furyl group. Examples of the acid group include a carboxyl group, a phosphoric acid group, a sulfo group, and a phenolic hydroxy group. Examples of the polymerizable group include ethylenically unsaturated bond-containing groups such as a vinyl group, a (meth)allyl group, and a (meth)acryloyl group. In a case where the furyl group-containing polymer includes a repeating unit having an acid group, the acid value of the furyl group-containing polymer is preferably 10 to 200 mgKOH/g and more preferably 40 to 130 mgKOH/g. The proportion of the repeating unit having an acid group in all repeating units of the furyl group-containing polymer is preferably 2 to 25 mass %. The lower limit is preferably 4 mass % or more and more preferably 5 mass % or more. The upper limit is preferably 20 mass % or less and more preferably 15 mass % or less. In a case where the furyl group-containing polymer includes a repeating unit having a polymerizable group, the proportion of the repeating unit having a polymerizable group in all repeating units of the furyl group-containing polymer is preferably 20 to 60 mass %. The lower limit is preferably 25 mass % or more and more preferably 30 mass % or more. The upper limit is preferably 55 mass % or less and more preferably 50 mass % or less. In a case where the furyl group-containing polymer includes a repeating unit having a polymerizable group, it is easy to form a cured film having more excellent solvent resistance and the like.

The furyl group-containing polymer can be produced by a method described in paragraphs “0052” to “0101” of JP2017-194662A.

The content of the furyl group-containing compound in the total solid content of the coloring composition is preferably 0.1 to 70 mass %. The lower limit is preferably 2.5 mass % or more, more preferably 5.0 mass % or more, and still more preferably 7.5 mass % or more. The upper limit is preferably 65 mass % or less, more preferably 60 mass % or less, and still more preferably 50 mass % or less.

In addition, in a case where the furyl group-containing polymer is used as the furyl group-containing compound, the content of the furyl group-containing polymer in the resin included in the coloring composition is preferably 0.1 to 100 mass %. The lower limit is preferably 10 mass % or more and more preferably 15 mass % or more. The upper limit is preferably 90 mass % or less and more preferably 80 mass % or less.

In addition, in a case where the resin used in the coloring composition according to the embodiment of the present invention includes the above-described resin b1, and the furyl group-containing polymer is used as the furyl group-containing compound, the content of the furyl group-containing polymer is preferably 10 to 200 parts by mass with respect to 100 parts by mass of the resin b1. The upper limit is preferably 175 parts by mass or less and preferably 150 parts by mass or less. The lower limit is preferably 25 parts by mass or more and preferably 150 parts by mass or more. By using the resin b1 and the furyl group-containing polymer in combination, it is easy to form a cured film having excellent curing properties at a low temperature and having excellent spectral characteristics. Further, in a case where the proportion of both is within the above-described range, an effect that durability of the film to be obtained can be further improved can be expected.

<<Compound having Epoxy Group>>

The coloring composition according to the embodiment of the present invention can further contain a compound having an epoxy group. As the compound having an epoxy group, a compound having two or more epoxy groups in one molecule is preferable. It is preferable to have 2 to 100 epoxy groups in one molecule. The upper limit is, for example, 10 or less or 5 or less. The epoxy equivalent (=the molecular weight of the compound having an epoxy group/the number of epoxy groups) of the compound having an epoxy group is preferably 500 g/eq or less, more preferably 100 to 400 g/eq, and still more preferably 100 to 300 g/eq. The compound having an epoxy group may be a low-molecular-weight compound (for example, a molecular weight of less than 1,000) or a high-molecular-weight compound (macromolecule) (for example, a molecular weight of 1,000 or more, and in a case of a polymer, a weight-average molecular weight of 1,000 or more). The molecular weight (in a case of the polymer, the weight-average molecular weight) of the compound having an epoxy group is preferably 200 to 100,000 and more preferably 500 to 50,000. The upper limit of the molecular weight (in a case of the polymer, the weight-average molecular weight) is preferably 3000 or less, more preferably 2000 or less, and still more preferably 1500 or less.

As the epoxy compound having an epoxy group, compounds described in paragraphs “0034” to “0036” of JP2013-011869A, paragraphs “0147” to “0156” of JP2014-043556A, and paragraphs “0085” to “0092” of JP2014-089408A, and compounds described in JP2017-179172A can also be used, the contents of which are incorporated herein by reference.

In a case where the coloring composition according to the embodiment of the present invention contains a compound having an epoxy group, the content of the compound having an epoxy group in the total solid content of the coloring composition is preferably 0.1 to 40 mass %. The lower limit is more preferably 0.5 mass % or more and still more preferably 1 mass % or more. The upper limit is more preferably 30 mass % or less and still more preferably 20 mass % or less. These compounds having an epoxy group may be used singly or in combination of two or more kinds thereof. In a case where two or more kinds thereof are used in combination, the total content thereof is preferably within the above-described range.

<<Solvent>>

The coloring composition according to the embodiment of the present invention preferably contains a solvent. Examples of the solvent include an organic solvent.

Basically, the solvent is not particularly limited as long as it satisfies the solubility of the respective components and the application properties of the coloring composition. Examples of the organic solvent include an ester solvent, a ketone solvent, an alcohol solvent, an amide solvent, an ether solvent, and a hydrocarbon solvent. With regard to details thereof, reference can be made to the description in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, a solvent having a low metal content is preferably used. For example, the metal content in the solvent is preferably 10 mass parts per billion (ppb) or less. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the solvent in the coloring composition is preferably 60 to 95 mass %. The upper limit is preferably 90 mass % or less, more preferably 87.5 mass % or less, and still more preferably 85 mass % or less. The lower limit is preferably 65 mass % or more, more preferably 70 mass % or more, and still more preferably 75 mass % or more. The solvent may be used singly or in combination of two or more kinds thereof. In a case where two or more kinds thereof are used in combination, the total content thereof is preferably within the above-described range.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be infiltrated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause cross-linking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or coloring composition produced by mixing these compounds.

<<Pigment Derivative>>

The coloring composition according to the embodiment of the present invention can contain a pigment derivative. Examples of the pigment derivative include a compound having a structure in which a part of a chromophore is substituted with an acid group, a basic group, or a phthalimidomethyl group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. As the acid group included in the pigment derivative, a sulfo group or a carboxyl group is preferable and a sulfo group is more preferable. As the basic group included in the pigment derivative, an amino group is preferable and a tertiary amino group is more preferable. Specific examples of the pigment derivative include compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraph “0082” of WO2017/038252A, paragraph “0171” of JP2015-151530A, paragraphs “0162” to “0183” of JP2011-252065A, JP2003-081972A, JP5299151B, JP2015-172732A, JP2014-199308A, JP2014-085562A, JP2014-035351A, and JP2008-081565A.

The content of the pigment derivative is preferably 0.1 to 30 parts by mass with respect to 100 parts by mass of the total amount of C. I. Pigment Blue 15:3, C. I. Pigment Blue 15:4, and C. I. Pigment Yellow 150. The lower limit is preferably 0.25 parts by mass or more, more preferably 0.5 parts by mass or more, still more preferably 0.75 parts by mass or more, and particularly preferably 1 part by mass or more. In addition, the upper limit is preferably 25 parts by mass or less, more preferably 20 parts by mass or less, and still more preferably 15 parts by mass or less. In a case where the content of the pigment derivative is within the above-described range, an effect that temporal stability is further improved is obtained. The pigment derivative may be used singly or in combination of two or more kinds thereof. In a case where two or more kinds thereof are used in combination, the total content thereof is preferably within the above-described range.

<<Curing Accelerator>>

For the purpose of promoting the reaction of polymerizable compounds or lowering a curing temperature, a curing accelerator may be added to the coloring composition according to the embodiment of the present invention. Examples of the curing accelerator include a polyfunctional thiol compound having two or more mercapto groups in a molecule. The polyfunctional thiol compound may also be added for the purpose of alleviating problems in stability, odor, resolution, developability, adhesiveness, or the like. The polyfunctional thiol compound is preferably secondary alkanethiols and more preferably a compound represented by Formula (T1).

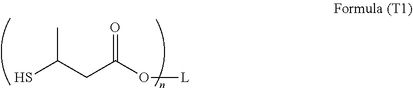

(in Formula (T1), n represents an integer of 2 to 4, and L represents a divalent to tetravalent linking group)

In Formula (T1), the linking group L is preferably an aliphatic group having 2 to 12 carbon atoms, and it is particularly preferable that n is 2 and L is an alkylene group having 2 to 12 carbon atoms.

In addition, as the curing accelerator, a methylol-based compound (for example, the compounds exemplified as a crosslinking agent in paragraph “0246” of JP2015-034963A), amines, phosphonium salts, amidine salts, and amide compounds (each of which is the curing agent described in, for example, paragraph “0186” of JP2013-041165A), base generators (for example, the ionic compounds described in JP2014-055114A), cyanate compounds (for example, the compounds described in paragraph “0071” of JP2012-150180A), alkoxysilane compounds (for example, the alkoxysilane compounds having an epoxy group, described in JP2011-253054A), onium salt compounds (for example, the compounds exemplified as an acid generator in paragraph “0216” of JP2015-034963A, and the compounds described in JP2009-180949A), or the like can also be used.

In a case where the coloring composition according to the embodiment of the present invention contains a curing accelerator, the content of the curing accelerator is preferably 0.3 to 8.9 mass % and more preferably 0.8 to 6.4 mass % with respect to the total solid content of the coloring composition.

<<Silane Coupling Agent>>

The coloring composition according to the embodiment of the present invention can contain a silane coupling agent. As the silane coupling agent, a silane compound having at least two kinds of functional groups having different reactivity in one molecule is preferable. The silane coupling agent is preferably a silane compound having at least one group selected from a vinyl group, an epoxy group, a styrene group, a methacryl group, an amino group, an isocyanurate group, a ureido group, a mercapto group, a sulfide group, or an isocyanate group, and an alkoxy group. Specific examples of the silane coupling agent include N-2-(aminoethyl)-3-aminopropyl methyldimethoxysilane (KBM-602, manufactured by Shin-Etsu Chemical Co., Ltd.), N-2-(aminoethyl)-3-aminopropyl trimethoxysilane (KBM-603, manufactured by Shin-Etsu Chemical Co., Ltd.), 3-aminopropyl trimethoxysilane (KBM-903, manufactured by Shin-Etsu Chemical Co., Ltd.), 3-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraphs “0155” to “0158” of JP2013-254047A, the contents of which are incorporated herein by reference. In a case where the coloring composition according to the embodiment of the present invention contains a silane coupling agent, the content of the silane coupling agent is preferably 0.001 to 20 mass %, more preferably 0.01 to 10 mass %, and particularly preferably 0.1 mass % to 5 mass % with respect to the total solid content of the coloring composition.

The coloring composition according to the embodiment of the present invention may include one kind or two or more kinds of the silane coupling agents. In a case where two or more kinds thereof are included, the total amount thereof is preferably within the above-described range.

<<Polymerization Inhibitor>>

The coloring composition according to the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxyamine salt (an ammonium salt, a cerous salt, or the like). In a case where the coloring composition according to the embodiment of the present invention contains a polymerization inhibitor, the content of the polymerization inhibitor in the total solid content of the coloring composition is preferably 0.0001 to 5 mass %. The coloring composition according to the embodiment of the present invention may include one kind or two or more kinds of the polymerization inhibitors. In a case where two or more kinds thereof are included, the total amount thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used. In a case where the coloring composition according to the embodiment of the present invention contains an ultraviolet absorber, the content of the ultraviolet absorber is preferably 0.1 to 10 mass %, more preferably 0.1 to 5 mass %, and particularly preferably 0.1 to 3 mass % with respect to the total solid content of the coloring composition. In addition, the ultraviolet absorber may be used singly or in combination of two or more kinds thereof. In a case where two or more kinds thereof are used, the total content thereof is preferably within the above-described range.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraphs “0238” to “0245” of WO2015/166779A, the contents of which are incorporated herein by reference.

In the present invention, it is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

The fluorine content in the fluorine-based surfactant is preferably 3 to 40 mass %, more preferably 5 to 30 mass %, and particularly preferably 7 to 25 mass %. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used. Examples of such a fluorine-based surfactant include fluorine-based surfactants described in JP2016-216602A, the contents of which are incorporated herein by reference.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraphs “0016” to “0037” of JP2010-032698A, or the following compounds are also exemplified as the fluorine-based surfactant used in the present invention.

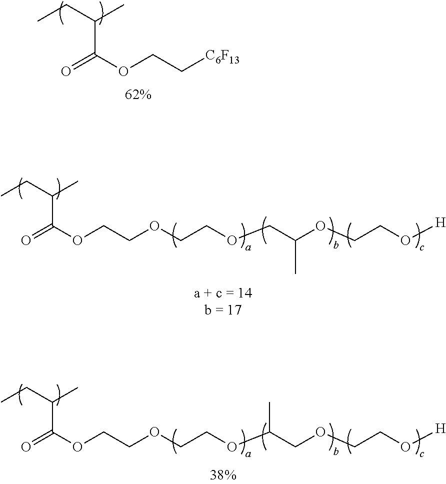

The weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer including a repeating unit having an ethylenically unsaturated bond-containing group in the side chain can be used. Specific examples thereof include compounds described in paragraphs “0050” to “0090” and paragraphs “0289” to “0295” of JP2010-164965A, and for example, MEGAFACE RS-101, RS-102, RS-718K, and RS-72-K manufactured by DIC Corporation. In addition, as the fluorine-based surfactant, compounds described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil & Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

The content of the surfactant in the total solid content of the coloring composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<<Other Additives>>

Various additives such as a filler, an adhesion promoter, an antioxidant, and an aggregation inhibitor can be blended into the coloring composition according to the embodiment of the present invention, as desired. Examples of these additives include the additives described in paragraphs “0155” and “0156” of JP2004-295116A, the contents of which are incorporated herein by reference. In addition, as the antioxidant, for example, a phenol compound, a phosphorus-based compound (for example, compounds described in paragraph “0042” of JP2011-090147A), a thioether compound, or the like can be used.

Examples of a commercially available product thereof include ADK STAB series (AO-20, AO-30, AO-40, AO-50, AO-50F, AO-60, AO-60G, AO-80, AO-330, and the like) manufactured by ADEKA Corporation. In addition, as the antioxidant, polyfunctional hindered amine antioxidants described in WO2017/006600A, antioxidants described in WO2017/164024A, and antioxidants described in paragraphs “0023” to “0048” of JP6268967B can also be used. In the present invention, the antioxidant may be used singly or in combination of two or more kinds thereof. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Specific examples of the potential antioxidant include compounds described in WO2014/021023A, WO2017/030005A, and JP2017-008219A. Examples of a commercially available product thereof include ADEKA ARKLS GPA-5001 (manufactured by ADEKA Corporation). In addition, the coloring composition according to the embodiment of the present invention can contain sensitizers or light stabilizers described in paragraph “0078” of JP2004-295116A, thermal polymerization inhibitors described in paragraph “0081” of the same publication, or storage stabilizers described in paragraph “0242” of JP2018-091940A.

In the coloring composition according to the embodiment of the present invention, the content of liberating metal which is not bonded to or coordinated with a pigment or the like is preferably 100 ppm or less, more preferably 50 ppm or less, and still more preferably 10 ppm or less, it is particularly preferable to not contain the liberating metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberating metal include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the coloring composition according to the embodiment of the present invention, the content of liberating halogen which is not bonded to or coordinated with a pigment or the like is preferably 100 ppm or less, more preferably 50 ppm or less, and still more preferably 10 ppm or less, it is particularly preferable to not contain the liberating halogen substantially. Examples of halogen include F, Cl, Br, I, and anions thereof. Examples of a method for reducing liberating metals and halogens in the coloring composition include washing with ion exchange water, filtration, ultrafiltration, and purification with an ion exchange resin.

<Storage Container>

A storage container of the coloring composition according to the embodiment of the present invention is not particularly limited, and a known storage container can be used. In addition, as the storage container, in order to suppress infiltration of impurities into the raw materials or the coloring composition, a multilayer bottle in which a container inner wall having a six-layer structure is formed of six kinds of resins or a bottle in which a container interior wall having a seven-layer structure is formed of six kinds of resins is preferably used. Examples of such a container include a container described in JP2015-123351A.

<Method for Producing Coloring Composition>

The coloring composition according to the embodiment of the present invention can be produced by mixing the above-described components with each other. During the production of the coloring composition, all the components may be dissolved or dispersed in a solvent at the same time to produce the coloring composition. Optionally, two or more solutions or dispersion liquids in which the respective components are appropriately blended may be prepared, and the solutions or dispersion liquids may be mixed with each other during use (during application) to produce the coloring composition.

In addition, in the production of the coloring composition, a process of dispersing particles such as pigments may be included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph “0022” of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the coloring composition, it is preferable that the coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultra-high molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be more reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all of which are manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Cured Film>

The cured film according to the embodiment of the present invention is obtained by using the above-described coloring composition according to the embodiment of the present invention. The cured film according to the embodiment of the present invention can be preferably used as a color filter. In particular, the cured film according to the embodiment of the present invention can be preferably used as a green pixel of a color filter. The film thickness of the cured film can be appropriately adjusted depending on purposes. For example, the film thickness is preferably 0.5 to 3.0 μm. The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less.

In the transmission spectrum to light having a wavelength range of 400 to 700 nm in a thickness direction of the film, the cured film according to the embodiment of the present invention has a peak value of transmittance in a wavelength range of 495 to 525 nm. In addition, the difference (λ^{T50L}−λ^{T50S}) between a wavelength (hereinafter, also referred to as λ^{T50L}) on the longer wavelength side than the wavelength of the peak value, at which the transmittance is 50% of the peak value, and a wavelength (hereinafter, also referred to as λ^{T50S}) on the shorter wavelength side than the wavelength of the peak value, at which the transmittance is 50% of the peak value, is preferably 65 to 90 nm, more preferably 70 to 85 nm, and still more preferably 75 to 80 nm.

In addition, the difference (λ^{Tmax}−λ^{T50S}) between the wavelength (hereinafter, also referred to as λ^{Tmax}) of the peak value of transmittance and the wavelength (λ^{T50S}) on the shorter wavelength side than the wavelength of the peak value, at which the transmittance is 50% of the peak value, is preferably 15 to 40 nm, more preferably 20 to 35 nm, and still more preferably 25 to 30 nm.

In addition, the difference (λ^{T50L}−λ^{Tmax}) between the wavelength (λ^{T50L}) on the longer wavelength side than the wavelength of the peak value, at which the transmittance is 50% of the peak value, and the wavelength (λ^{Tmax}) of the peak value of transmittance is preferably 35 to 60 nm, more preferably 40 to 55 nm, and still more preferably 45 to 50 nm.

It is preferable that the cured film according to the embodiment of the present invention has a maximum transmittance of 65% or more to light having a wavelength of 495 to 525 nm and has an average transmittance of 60% or more to light having a wavelength of 495 to 525 nm, and it is more preferable to have a maximum transmittance of 70% or more to light having a wavelength of 495 to 525 nm and have an average transmittance of 65% or more to light having a wavelength of 495 to 525 nm. In addition, the transmittance to light having a wavelength of 450 nm is preferably 10% or less, more preferably 5% or less, and still more preferably 1% or less. In addition, the maximum transmittance to light having a wavelength of 400 to 450 nm is preferably 10% or less, more preferably 5% or less, and still more preferably 1% or less. In addition, the transmittance to light having a wavelength of 620 nm is preferably 10% or less, more preferably 5% or less, and still more preferably 1% or less. In addition, the maximum transmittance to light having a wavelength of 600 to 625 nm is preferably 10% or less, more preferably 5% or less, and still more preferably 1% or less. In addition, each transmittance to light having a wavelength of 480 nm and light having a wavelength of 570 nm is preferably 50% or less and more preferably 45% or less. In addition, each transmittance to light having a wavelength of 460 nm and light having a wavelength of 580 nm is preferably 20% and more preferably 15% or less.

<Color Filter>

The color filter according to the embodiment of the present invention includes the above-described cured film according to the embodiment of the present invention. A preferred aspect of the color filter according to the embodiment of the present invention includes an aspect in which a green pixel obtained by using the coloring composition according to the embodiment of the present invention, a red pixel, and a blue pixel are included. The color filter according to the embodiment of the present invention can be used for a solid-state imaging element or a display device.

The red pixel preferably includes a red colorant. The content of the red colorant in colorants included in the red pixel is preferably 30 mass % or more and more preferably 40 mass % or more. The upper limit of the content of the red colorant in colorants included in the red pixel may be 100 mass %, 99 mass % or less, 95 mass % or less, or 90 mass % or less. In addition, the red pixel preferably includes 40 mass % or more of the red colorant, more preferably includes 50 mass % or more of the red colorant, and still more preferably includes 60 mass % or more of the red colorant. In addition, the upper limit of the content of the red colorant is preferably 80 mass % or less, more preferably 70 mass % or less, and still more preferably 60 mass % or less.

Examples of the red colorant include red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (azo-based), and 296 (azo-based), and C. I. Pigment Red 177, 254, 269, or 272 is more preferable.

It is more preferable that the red pixel further includes a yellow colorant in addition to the red colorant. The content of the yellow colorant is preferably 3 to 60 parts by mass, more preferably 5 to 50 parts by mass, and still more preferably 10 to 40 parts by mass with respect to 100 parts by mass of the red colorant. Examples of the yellow colorant include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 231, 232 (methine-based), and 233 (quinoline-based), and C. I. Pigment Yellow 138, 139, 150, or 185 is more preferable.

The red pixel preferably has spectral characteristics with low transmittance up to a wavelength of 580 nm.

The blue pixel preferably includes a blue colorant. The content of the blue colorant in colorants included in the blue pixel is preferably 40 mass % or more and more preferably 60 mass % or more. In addition, the blue pixel preferably includes 20 mass % or more of the blue colorant, more preferably includes 25 mass % or more of the blue colorant, and still more preferably includes 30 mass % or more of the blue colorant. The upper limit of the content of the blue colorant is preferably 80 mass % or less, more preferably 70 mass % or less, and still more preferably 60 mass % or less. Examples of the blue colorant include blue pigments such as C. I. Pigment Blue 1, 2, 15, 15:1, 15:2, 15:6, 16, 22, 29, 60, 64, 66, 79, 80, 87 (monoazo-based), and 88 (methine-based), and C. I. Pigment Blue 15:6 is preferable.

It is more preferable that the blue pixel further includes at least one selected from a violet colorant and a red colorant in addition to the blue colorant. The content of the violet colorant is preferably 10 to 90 parts by mass, more preferably 20 to 75 parts by mass, and still more preferably 30 to 60 parts by mass with respect to 100 parts by mass of the blue colorant. Examples of the violet colorant and red colorant include violet pigments such as C. I. Pigment Violet 1, 19, 23, 27, 32, 37, 42, 60 (triarylmethane-based), and 61 (xanthene-based), and xanthene compounds. Examples of the xanthene compound include salt-forming compounds obtained by reacting a resin having a cationic group in the side chain with a xanthene-based acid dye, which are described in paragraphs “0025” to “0077” of JP2016-180834A.

It is preferable that the blue pixel has a high peak transmittance and has steep slope-shaped spectral characteristics.

<Structure Body>

The structure body according to the embodiment of the present invention includes the above-described green pixel obtained by using the coloring composition according to the embodiment of the present invention, a red pixel, and a blue pixel.

It is preferable that the green pixel has the spectral characteristics described in the section of the cured film according to the embodiment of the present invention. In addition, it is preferable that the red pixel and the blue pixel have the spectral characteristics described in the section of the color filter.

<Method for Forming Pixel>

A method for forming pixels will be described. The green pixel can be formed, for example, by using the coloring composition according to the embodiment of the present invention.

The method for forming pixels preferably includes a step of forming a coloring composition layer by applying a coloring composition to a support, a step of exposing the coloring composition layer in a patterned manner, and a step of developing the coloring composition layer after exposure. It is preferable that the formation of pixels is performed at a temperature of 150° C. or lower throughout the entire steps. In the present invention, “performing at a temperature of 150° C. or lower throughout the entire steps” means that all steps of forming pixels using the coloring composition are performed at a temperature of 150° C. or lower. In a case where a heating step is further provided after developing the coloring composition layer after exposure, “performing at a temperature of 150° C. or lower throughout the entire steps” means that this heating step is also performed at a temperature of 150° C. or lower. Hereinafter, each step will be described in detail.

In the step of forming a coloring composition layer, the coloring composition is applied to a support to form the coloring composition layer. Examples of the support include a glass substrate, a polycarbonate substrate, a polyester substrate, an aromatic polyamide substrate, a polyamide-imide substrate, and a polyimide substrate. An organic light emitting layer may be formed on these substrates. In addition, an undercoat layer may be provided on the substrate so as to improve adhesiveness to an upper layer, prevent the diffusion of substances, or planarize the surface.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and a metal mask printing; a transfer method using a mold or the like; and a nanoimprinting method. The application method using an ink jet method is not particularly limited, and examples thereof include a method (in particular, pp. 115 to 133) described in “Extension of Use of Ink Jet—Infinite Possibilities in Patent—” (published in February, 2005, S.B. Research Co., Ltd.) and methods described in JP2003-262716A, JP2003-185831A, JP2003-261827A, JP2012-126830A, and JP2006-169325A. In addition, with regard to the method of applying the coloring composition, reference can be made to the description in WO2017/030174A and WO2017/018419A, the contents of which are incorporated herein by reference.

The coloring composition layer formed on the support may be dried (pre-baked). In a case where pre-baking is performed, the pre-baking temperature is preferably 80° C. or lower, more preferably 70° C. or lower, still more preferably 60° C. or lower, and particularly preferably 50° C. or lower. The lower limit may be, for example, 40° C. or higher. The pre-baking time is preferably 10 to 3600 seconds. Pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. As a result, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the coloring composition layer may be irradiated with light continuously to expose the composition layer, or the coloring composition layer may be irradiated with light in a pulse to expose the coloring composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

In addition, it is also preferable to irradiate with light (preferably i-rays) having a wavelength of more than 350 nm and 380 nm or less with an exposure amount of 1 J/cm² or more for exposure. By exposing in this way, the coloring composition layer can be sufficiently cured, and a pixel having excellent characteristics such as solvent resistance can be produced.

Next, the coloring composition layer after exposure is developed. That is, an unexposed area of the coloring composition layer is removed by development to form a pattern (pixel). The unexposed area of the coloring composition layer can be removed by development using a developer. Thus, the coloring composition layer of the unexposed area in the exposing step is eluted into the developer, and as a result, only a photocured portion remains. Examples of the developer include an organic solvent and an alkali developer, and an alkali developer is preferable. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

The alkaline developer is preferably an alkaline aqueous solution in which the alkaline agent is diluted with pure water. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is also preferable to perform an additional exposure treatment or a heat treatment (post-baking) after carrying out drying. The additional exposure treatment or the post-baking is a curing treatment after development in order to complete curing.

In a case where the post-baking is performed, the heating temperature is preferably 100° C. to 150° C. The upper limit of the heating temperature is preferably 120° C. or lower. The heating time is preferably 1 minute or more, more preferably 5 minutes or more, and still more preferably 10 minutes or more. The upper limit thereof is not particularly limited, but from the viewpoint of productivity, 20 minutes or less is preferable. It is also preferable that the post-baking is performed in an atmosphere of an inert gas. According to this aspect, thermal polymerization can proceed with very high efficiency without being hindered by oxygen, and even in a case where a pixel is produced at a temperature of 120° C. or lower throughout the entire steps, it is possible to produce a pixel having high flatness and excellent characteristics such as solvent resistance. Examples of the inert gas include nitrogen gas, argon gas, and helium gas, and nitrogen gas is preferable. The oxygen concentration during post-baking is preferably 100 ppm or less.

In a case of performing the additional exposure treatment, it is preferable to irradiate with light having a wavelength of 254 to 350 nm for exposure. As a more preferred aspect, it is preferable that, in the step of exposing the coloring composition layer (exposure before development) in a patterned manner, the coloring composition layer is exposed by irradiating the coloring composition layer with light having a wavelength of more than 350 nm and 380 nm or less (preferably light having a wavelength of 355 to 370 nm and more preferably i-rays), and in the additional exposure treatment (exposure after development), the coloring composition layer after development is exposed by irradiating the coloring composition layer with light having a wavelength of 254 to 350 nm (preferably light having a wavelength of 254 nm). According to this aspect, the coloring composition layer can be moderately cured at the first exposure (exposure before development), and the entire coloring composition layer can be cured almost completely at the next exposure (exposure after development). As a result, the coloring composition layer can be sufficiently cured even under low temperature conditions, and it is possible to form a pixel having excellent characteristics such as solvent resistance, adhesiveness, and rectangularness. In a case where the exposure is performed in two stages as described above, in the coloring composition, it is preferable that a photopolymerization initiator including the photopolymerization initiator A1 having a light absorption coefficient of 1.0×10³ mL/gcm or more at a wavelength of 365 nm in methanol and the photopolymerization initiator A2 having a light absorption coefficient of 1.0×10² mL/gcm or less at a wavelength of 365 nm in methanol and having a light absorption coefficient of 1.0×10³ mL/gcm or more at a wavelength of 254 nm in methanol is used as the photopolymerization initiator.

The exposure after development can be performed using, for example, an ultraviolet photoresist curing device. The light having a wavelength of 254 to 350 nm and other light (for example, i-rays) may irradiate from the ultraviolet photoresist curing device.

The irradiation dose (exposure amount) in the exposure before development is, for example, preferably 30 to 1500 mJ/cm² and more preferably 50 to 1000 mJ/cm². The irradiation dose (exposure amount) in the exposure after development is preferably 30 to 4000 mJ/cm² and more preferably 50 to 3500 mJ/cm². The difference between the wavelength of the light used for the exposure before development and the wavelength of the light used for the exposure after development is preferably 200 nm or less and more preferably 100 to 150 nm.

<Display Device>

The display device according to an embodiment of the present invention has the above-described cured film according to the embodiment of the present invention. Examples of the display device include a liquid crystal display device or an organic electroluminescent display device. The definitions of display devices or the details of the respective display devices are described in, for example, “Electronic Display Device (written by Akio Sasaki, Kogyo Chosakai Publishing Co., Ltd., published in 1990)”, “Display Device (written by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

The organic electroluminescent display device may be an organic electroluminescent display device which has a light source composed of a white organic electroluminescent element. It is preferable that the white organic electroluminescent element has a tandem structure. The tandem structure of the organic electroluminescent element is described in, for example, JP2003-045676A, or pp. 326 to 328 of “Forefront of Organic EL Technology Development-Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

<Solid-State Imaging Element>

The coloring composition and cured film according to the embodiment of the present invention can also be used for a solid-state imaging element. The configuration of the solid-state imaging element is not particularly limited as long as the solid-state imaging element is configured to include the cured film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device protective film formed of silicon nitride or the like, which is formed to cover the entire surface of the light-shielding film and the light receiving portion of the photodiodes, on the light-shielding film; and have the cured film according to the embodiment of the present invention on the device protective film. Further, the solid-state imaging element may also be configured, for example, such that it has a light collecting unit (for example, a microlens, which is the same hereinafter) on the device protective film and under the cured film according to the embodiment of the present invention (a side closer to the substrate), or has a light collecting unit on the cured film according to the embodiment of the present invention. In addition, the cured film according to the embodiment of the present invention may be embedded in a space partitioned by a partition wall, for example, in a lattice form. In this case, it is preferable that the partition wall has a lower refractive index than the cured film according to the embodiment of the present invention. Examples of an imaging device having such a structure include devices described in JP2012-227478A, JP2014-179577A, WO2018/043654A, and US2018/0040656A. An imaging device including the solid-state imaging element can also be used as a vehicle camera, a surveillance camera, and the like, in addition to a digital camera or electronic apparatus (mobile phones or the like) having an imaging function.

### EXAMPLES

Hereinafter, the present invention will be described in more detail with reference to Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

(Pigment Dispersion Liquids P-G1 to P-G11, P-Gr1, and P-Gr2)

Raw materials described in the following table were mixed, and then using zirconia beads having a diameter of 1 mm, the raw materials were dispersed for 5 hours with an Eiger mill (“Mini Model M-250 MKII” manufactured by Eiger Japan Co., Ltd.). Thereafter, the mixture was filtered through a filter having a pore size of 5 μm to produce a pigment dispersion liquid. The numerical values described in the following table indicate parts by mass. The pigment ratio in the pigment dispersion liquid is also described.

TABLE 1

| | | | | | Resin | | Pigment ratio |
|---|---|---|---|---|---|---|---|
| | | | | Dispersant | solution | Solvent | (PB15:3 + |
| | PB15:3 | PB15:4 | PY150 | 1 | 1 | 1 | PB15:4)/PY150 |
| Pigment dispersion | | 3.33 | 8.34 | 6.09 | 5.53 | 76.71 | 40/100 |
| liquid P-G1 | | | | | | | |
| Pigment dispersion | | 3.05 | 8.62 | 6.09 | 5.53 | 76.71 | 35/100 |
| liquid P-G2 | | | | | | | |
| Pigment dispersion | | 3.63 | 8.04 | 6.09 | 5.53 | 76.71 | 45/100 |
| liquid P-G3 | | | | | | | |
| Pigment dispersion | | 3.91 | 7.76 | 6.09 | 5.53 | 76.71 | 50/100 |
| liquid P-G4 | | | | | | | |
| Pigment dispersion | | 4.15 | 7.52 | 6.09 | 5.53 | 76.71 | 55/100 |
| liquid P-G5 | | | | | | | |
| Pigment dispersion | 3.33 | | 8.34 | 6.09 | 5.53 | 76.71 | 40/100 |
| liquid P-G6 | | | | | | | |
| Pigment dispersion | 3.05 | | 8.62 | 6.09 | 5.53 | 76.71 | 35/100 |
| liquid P-G7 | | | | | | | |
| Pigment dispersion | 3.63 | | 8.04 | 6.09 | 5.53 | 76.71 | 45/100 |
| liquid P-G8 | | | | | | | |
| Pigment dispersion | 3.91 | | 7.76 | 6.09 | 5.53 | 76.71 | 50/100 |
| liquid P-G9 | | | | | | | |
| Pigment dispersion | 4.15 | | 7.52 | 6.09 | 5.53 | 76.71 | 55/100 |
| liquid P-G10 | | | | | | | |
| Pigment dispersion | 1.67 | 1.67 | 8.33 | 6.09 | 5.53 | 76.71 | 40/100 |
| liquid P-G11 | | | | | | | |
| Pigment dispersion | | 2.92 | 8.75 | 6.09 | 5.53 | 76.71 | 33/100 |
| liquid P-Gr1 | | | | | | | |
| Pigment dispersion | 2.92 | | 8.75 | 6.09 | 5.53 | 76.71 | 33/100 |
| liquid P-Gr2 | | | | | | | |

The raw materials described by abbreviations shown in the above table are as follows.

PB15:3: C. I. Pigment Blue 15:3

PB15:4: C. I. Pigment Blue 15:4

PY150: C. I. Pigment Yellow 150

Dispersant 1: Disperbyk-2001 (manufactured by BYK Chemie, concentration of solid contents: 46 mass %)

Resin solution 1: resin solution 1 prepared by the following method

90.0 parts by mass of cyclohexanone was charged into a reaction vessel equipped with a stirrer, a thermometer, a dropping device, a reflux condenser, and a gas introduction tube, and was heated to 60° C. while injecting nitrogen gas into the vessel, and at the same temperature, a mixture of 20.0 parts by mass of methacrylic acid, 10.0 parts by mass of methyl methacrylate, 55.0 parts by mass of n-butyl methacrylate, 15 parts by mass of benzyl methacrylate, and 2.5 parts by mass of 2,2′-azobisisobutyronitrile was added dropwise thereto over 2 hours to perform a polymerization reaction. After the dropwise addition, the mixture was further reacted at 60° C. for 1 hour, 0.5 parts by mass of 2,2′-azobisisobutyronitrile dissolved in 10.0 parts by mass of propylene glycol monomethyl ether acetate was added thereto, and then stirring was continued at the same temperature for 3 hours to obtain a resin (Mw=30000). After cooling to room temperature, the reactant was diluted with cyclohexanone to adjust the concentration of solid contents to 20 mass %, thereby preparing the resin solution 1.

Solvent 1: propylene glycol monomethyl ether acetate (PGMEA)

<Preparation of Coloring Composition>

### Example 1

The following raw materials were mixed and stirred, and the obtained mixture was filtered through a nylon filter (manufactured by Nihon Pall Corporation) having a pore size of 0.45 μm to prepare a coloring composition having a concentration of solid contents of 19.05 mass %. The concentration of solid contents of the coloring composition was adjusted by the blending amount of a solvent (PGMEA).

Pigment dispersion liquid (pigment dispersion liquid P-G1) . . . 65 mass %

Photopolymerization initiator (initiator 1) . . . 2 mass %

Resin (resin A) . . . 5.5 mass %

Furyl group-containing compound (F1) . . . 5.5 mass %

Polymerizable compound (M1) . . . 2.6 mass %

Solvent (PGMEA) . . . remaining

### Examples 2 to 27 and Comparative Examples 1 and 2

Coloring compositions were prepared in the same manner as in Example 1 by changing the types and contents of the pigment dispersion liquid, the photopolymerization initiator, the resin, the furyl group-containing compound, the polymerizable compound, and the solvent as shown in the following table. The numerical values of the contents of the resin and the furyl group-containing compound are values expressed in terms of solid contents.

TABLE 2

| | Pigment Dispersion | | Photopolymerization | | | | Furyl group-containing | | Polymerizable | | |
|---|---|---|---|---|---|---|---|---|---|---|---|
| | liquid | | initiator | | Resin | | polymer | | compound | | |
| | | Content | | Content | | Content | | Content | | Content | |
| | Type | (mass %) | Type | (mass %) | Type | (mass %) | Type | (mass %) | Type | (mass %) | Solvent |
| Example 1 | P-G1 | 65 | Initiator 1 | 0.1 | Resin A | 4.33 | F1 | 6.5 | M1 | 2.6 | PGMEA |
| Example 2 | P-G2 | 65 | Initiator 1 | 0.1 | Resin A | 4.33 | F1 | 6.5 | M1 | 2.6 | PGMEA |
| Example 3 | P-G3 | 65 | Initiator 1 | 0.1 | Resin A | 4.33 | F1 | 6.5 | M1 | 2.6 | PGMEA |
| Example 4 | P-G4 | 65 | Initiator 1 | 0.1 | Resin A | 4.33 | F1 | 6.5 | M1 | 2.6 | PGMEA |
| Example 5 | P-G5 | 65 | Initiator 1 | 0.1 | Resin A | 4.33 | F1 | 6.5 | M1 | 2.6 | PGMEA |
| Example 6 | P-G1 | 65 | Initiator 1 | 0.1 | Resin A | 4.33 | F2 | 6.5 | M1 | 2.6 | PGMEA |
| Example 7 | P-G1 | 65 | Initiator 1 | 0.1 | Resin A | 4.33 | F1 | 6.5 | M2 | 0.8 | PGMEA |
| | | | | | | | | | M3 | 1.0 | |
| | | | | | | | | | M4 | 0.8 | |
| Example 8 | P-G1 | 65 | Initiator 1 | 0.1 | Resin A | 4.33 | F1 | 6.5 | M5 | 2.6 | PGMEA |
| Example 9 | P-G1 | 65 | Initiator 2 | 0.1 | Resin A | 4.33 | F1 | 6.5 | M1 | 2.6 | PGMEA |
| Example 10 | P-G1 | 65 | Initiator 3 | 0.1 | Resin A | 4.33 | F1 | 6.5 | M1 | 2.6 | PGMEA |
| Example 11 | P-G1 | 65 | Initiator 6 | 0.1 | Resin A | 4.33 | F1 | 6.5 | M1 | 2.6 | PGMEA |
| Example 12 | P-G1 | 65 | Initiator 1 | 0.1 | Resin A | 4.33 | F1 | 6.5 | M1 | 2.6 | PGMEA |
| | | | Initiator 4 | 0.1 | | | | | | | |
| Example 13 | P-G1 | 65 | Initiator 1 | 0.1 | Resin A | 4.33 | F1 | 6.5 | M1 | 2.6 | PGMEA |
| | | | Initiator 5 | 0.1 | | | | | | | |
| Example 14 | P-G1 | 65 | Initiator 1 | 0.1 | Resin A | 4.33 | F1 | 6.5 | M6 | 2.6 | PGMEA |
| Example 15 | P-G1 | 65 | Initiator 1 | 0.1 | Resin B | 4.33 | F1 | 6.5 | M1 | 2.6 | PGMEA |
| Example 16 | P-G1 | 65 | Initiator 1 | 0.1 | Resin C | 4.33 | F1 | 6.5 | M1 | 2.6 | PGMEA |
| Example 17 | P-G1 | 65 | Initiator 1 | 0.1 | — | — | F1 | 13 | M1 | 2.6 | PGMEA |
| Example 18 | P-G1 | 65 | Initiator 1 | 0.1 | Resin A | 8.66 | — | — | M1 | 2.6 | PGMEA |
| Example 19 | P-G1 | 65 | Initiator 1 | 0.1 | Resin A | 4.33 | F1 | 6.5 | M1 | 2.6 | PGMEA/PGME = 50/50 |
| | | | | | | | | | | | (mass ratio) |
| Example 20 | P-G1 | 65 | Initiator 1 | 0.1 | Resin A | 2.17 | F1 | 6.5 | M1 | 2.6 | PGMEA |
| | | | | | Resin C | 2.17 | | | | | |
| Example 21 | P-G1 | 65 | Initiator 1 | 1 | Resin A | 4.33 | F1 | 6.5 | M1 | 2.6 | PGMEA |
| | | | Initiator 4 | 1 | | | | | | | |
| Example 22 | P-G6 | 65 | Initiator 1 | 0.1 | Resin A | 4.33 | F1 | 6.5 | M1 | 2.6 | PGMEA |
| Example 23 | P-G7 | 65 | Initiator 1 | 0.1 | Resin A | 4.33 | F1 | 6.5 | M1 | 2.6 | PGMEA |
| Example 24 | P-G8 | 65 | Initiator 1 | 0.1 | Resin A | 4.33 | F1 | 6.5 | M1 | 2.6 | PGMEA |
| Example 25 | P-G9 | 65 | Initiator 1 | 0.1 | Resin A | 4.33 | F1 | 6.5 | M1 | 2.6 | PGMEA |
| Example 26 | P-G10 | 65 | Initiator 1 | 0.1 | Resin A | 4.33 | F1 | 6.5 | M1 | 2.6 | PGMEA |
| Example 27 | P-G11 | 65 | Initiator 1 | 0.1 | Resin A | 4.33 | F1 | 6.5 | M1 | 2.6 | PGMEA |
| Comparative | P-Gr1 | 65 | Initiator 1 | 0.1 | Resin A | 4.33 | F1 | 6.5 | M1 | 2.6 | PGMEA |
| Example 1 | | | | | | | | | | | |
| Comparative | P-Gr2 | 65 | Initiator 1 | 0.1 | Resin A | 4.33 | F1 | 6.5 | M1 | 2.6 | PGMEA |
| Example 2 | | | | | | | | | | | |

The raw materials described by abbreviations shown in the above table are as follows.

(Pigment Dispersion Liquid)

P-G1 to P-G11, P-Gr1, P-Gr2: pigment dispersion liquids P-G1 to P-G11, P-Gr1, and P-Gr2 described above

(Photopolymerization Initiator)

Initiator 1: Irgacure OXE02 (manufactured by BASF, compound having the following structure; light absorption coefficient at a wavelength of 365 nm in methanol is 7749 mL/gcm)

Initiator 2: Irgacure OXE01 (manufactured by BASF, compound having the following structure; light absorption coefficient at a wavelength of 365 nm in methanol is 6969 mL/gcm)

Initiator 3: compound having the following structure (light absorption coefficient at a wavelength of 365 nm in methanol is 18900 mL/gcm)

Initiator 4: compound having the following structure (light absorption coefficient at a wavelength of 365 nm in methanol is 48.93 mL/gcm, and light absorption coefficient at a wavelength of 254 nm in methanol is 3.0×10⁴ mL/gcm)

Initiator 5: compound having the following structure (light absorption coefficient at a wavelength of 365 nm in methanol is 88.64 mL/gcm, and light absorption coefficient at a wavelength of 254 nm in methanol is 3.3×10⁴ mL/gcm)

Initiator 6: compound having the following structure (light absorption coefficient at a wavelength of 365 nm in methanol is 13200 mL/gcm)

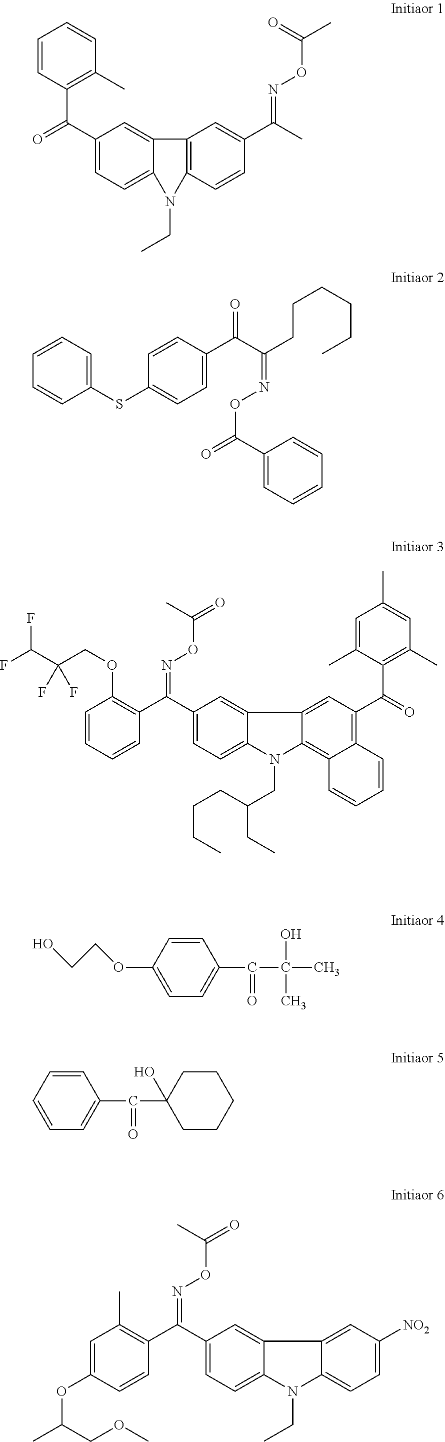

(Polymerizable Compound)

M1: ARONIX M-402 (manufactured by TOAGOSEI CO., LTD.; mixture of dipentaerythritol hexaacrylate and dipentaerythritol pentaacrylate)

M2: compound having the following structure (a+b+c=3)

M3: compound having the following structure (a+b+c=4)

M4: mixture of compounds having the following structure (compound of a+b+c=5: compound of a+b+c=6=3:1 (molar ratio))

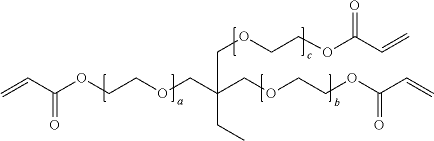

M5: compound having the following structure

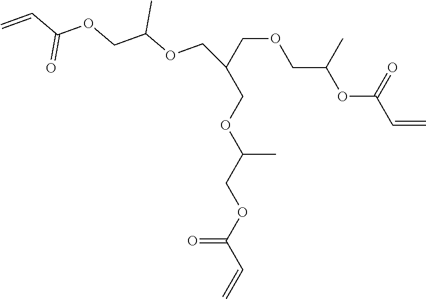 [SMILES: C=CC(=O)OCC(C)OCC(COCC(C)OC(=O)C=C)COC(C)COC(=O)C=C]

M6: ARONIX M-309 (manufactured by TOAGOSEI CO., LTD.; trimethylolpropane triacrylate)

(Resin)

Resin A: Resin Synthesized by the Following Method

70.0 parts by mass of cyclohexanone was charged into a separable four-neck flask equipped with a thermometer, a cooling pipe, a nitrogen gas introduction pipe, a dropping tube, and a stirrer, and was heated to 80° C., and after replacing the inside of the flask with nitrogen, from the dropping tube, a mixture of 13.3 parts by mass of n-butyl methacrylate, 4.6 parts by mass of 2-hydroxyethyl methacrylate, 4.3 parts by mass of methacrylic acid, 7.4 parts by mass of para-cumylphenol ethylene oxide-modified acrylate (ARONIX M110 manufactured by TOAGOSEI CO., LTD.), and 0.4 parts by mass of 2,2′-azobisisobutyronitrile was added dropwise thereto over 2 hours. After the dropwise addition, the reaction was continued for another 3 hours to obtain a 30 mass % solution of a resin A (Mw=26000).

Resin B: resin having the following structure (Mw=30000; numerical values described together with the main chain indicate molar ratio)

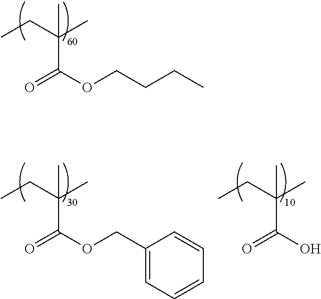

Resin C: Resin Synthesized by the Following Method

90.0 parts by mass of propylene glycol monomethyl ether acetate was charged into a reaction vessel equipped with a stirrer, a thermometer, a dropping device, a reflux condenser, and a gas introduction tube, and was heated to 60° C. while injecting nitrogen gas into the vessel, and at the same temperature, a mixture of 35.0 parts by mass of glycidyl methacrylate, 45.0 parts by mass of methyl methacrylate, and 2.5 parts by mass of 2,2′-azobisisobutyronitrile was added dropwise thereto over 2 hours to perform a polymerization reaction. After the dropwise addition, the mixture was further reacted at 60° C. for 1 hour, 0.5 parts by mass of 2,2′-azobisisobutyronitrile dissolved in 10.0 parts by mass of propylene glycol monomethyl ether acetate was added thereto, and then stirring was continued at the same temperature for 3 hours to obtain a copolymer. Subsequently, dry air was injected into the reaction vessel, 10.0 parts by mass of acrylic acid, 30.2 parts by mass of propylene glycol monomethyl ether acetate, 1.30 parts by mass of dimethylbenzylamine, and 0.26 parts by mass of methoquinone were added thereto, and the mixture was heated to 100° C. and stirred for 20 hours. Thereafter, the production of a target product was confirmed by measuring the acid value. Subsequently, 10.0 parts by mass of tetrahydrophthalic anhydride and 27.7 parts by mass of propylene glycol monomethyl ether acetate were added to the reaction vessel, and the mixture was stirred at 60° C. for 3 hours and then cooled to room temperature, and diluted with propylene glycol monomethyl ether acetate to obtain a 20 mass % solution of a resin C (Mw=12000).

(Furyl Group-Containing Compound)

F1: Furyl Group-Containing Compound F1 Synthesized by the Following Method

90.0 parts by mass of propylene glycol monomethyl ether acetate was charged into a reaction vessel equipped with a stirrer, a thermometer, a dropping device, a reflux condenser, and a gas introduction tube, and was heated to 60° C. while injecting nitrogen gas into the vessel, and at the same temperature, a mixture of 50.0 parts by mass of furfuryl methacrylate, 26.7 parts by mass of 2-methacryloyloxyethyl succinic acid, 23.3 parts by mass of 2-hydroxyethyl methacrylate, and 2.5 parts by mass of 2,2′-azobis(2,4-dimethylvaleronitrile) was added dropwise thereto over 2 hours to perform a polymerization reaction. After the dropwise addition, the mixture was further reacted at 60° C. for 1 hour, 0.5 parts by mass of 2,2′-azobis(2,4-dimethylvaleronitrile) dissolved in 10.0 parts by mass of propylene glycol monomethyl ether acetate was added thereto, and then stirring was continued at the same temperature for 3 hours to obtain a copolymer. After cooling to room temperature, the mixture was diluted with propylene glycol monomethyl ether acetate to obtain a 20 mass % solution of a furyl group-containing compound F1 (Mw=52000).

F2: Furyl Group-Containing Compound F2 Synthesized by the Following Method

90.0 parts by mass of propylene glycol monomethyl ether acetate was charged into a reaction vessel equipped with a stirrer, a thermometer, a dropping device, a reflux condenser, and a gas introduction tube, and was heated to 60° C. while injecting nitrogen gas into the vessel, and at the same temperature, a mixture of 50.0 parts by mass of furfuryl methacrylate, 10 parts by mass of methacrylic acid, 40.0 parts by mass of methyl methacrylate, and 5.0 parts by mass of 2,2′-azobis(2,4-dimethylvaleronitrile) was added dropwise thereto over 2 hours to perform a polymerization reaction. After the dropwise addition, the mixture was further reacted at 60° C. for 1 hour, 1.0 parts by mass of 2,2′-azobis(2,4-dimethylvaleronitrile) dissolved in 10.0 parts by mass of propylene glycol monomethyl ether acetate was added thereto, and then stirring was continued at the same temperature for 3 hours to obtain a copolymer. After cooling to room temperature, the mixture was diluted with propylene glycol monomethyl ether acetate to obtain a 20 mass % solution of a furyl group-containing compound F2 (Mw=26000).

(Solvent)

PGMEA: propylene glycol monomethyl ether acetate

PGME: propylene glycol methyl ether

<Production of Cured Film>

Each coloring composition was applied to a glass substrate using a spin coater such that the film thickness after drying was 1.4 μm, and dried on a hot plate at 100° C. for 2 minutes. Thereafter, using an ultra-high pressure mercury lamp, i-rays exposure was performed under conditions of an exposure illuminance of 20 mW/cm² and an exposure amount of 1 J/cm². The film was heated on a hot plate at 100° C. for 20 minutes and allowed to cool to form a cured film. In the production of the cured film, the temperature of the substrate was in a range of 20° C. to 100° C. throughout the entire steps.

<Evaluation>

(Spectroscopy)

Using a ultraviolet-visible-near infrared spectrophotometer (UV3600, manufactured by Shimadzu Corporation), the absorbance of the obtained cured film to light having a wavelength range of 300 to 800 nm was measured with a reference of the glass substrate to obtain the following wavelength 1, wavelength 2, wavelength 3, A⁴⁵⁰/A⁶²⁰, and wavelength difference 1.

The wavelength 1 is a wavelength at which an absorbance is the minimum among absorbances to light having a wavelength of 400 to 700 nm.

The wavelength 2 is a wavelength on the short wavelength side at which, in a case where an absorbance to light having a wavelength of 450 nm is defined as 1, an absorbance is 0.14.

The wavelength 3 is a wavelength on the long wavelength side at which, in a case where an absorbance to light having a wavelength of 450 nm is defined as 1, an absorbance is 0.14.

A⁴⁵⁰/A⁶²⁰ is a ratio of an absorbance A⁴⁵⁰ to light having a wavelength of 450 nm and an absorbance A⁶²⁰ to light having a wavelength of 620 nm.

The wavelength difference 1 is a wavelength difference between wavelengths on the long wavelength side and the short wavelength side, at which absorbances are 0.4 in a case where an absorbance to light having a wavelength of 450 nm is defined as 1.

(Light Resistance)

Light transmittance (transmittance) of the obtained cured film in a range of 400 to 700 nm was measured by using MCPD-3000 manufactured by OTSUKA ELECTRONICS Co., LTD.

Next, a UV cut filter (manufactured by AS ONE Corporation, KU-1000100) was mounted on the cured film produced above and a light resistance test was performed by using a weather meter (manufactured by Suga Test Instruments Co., Ltd., Xenon Weather Meter SX75) to irradiating light of 100,000 lx over 50 hours. The temperature inside the tester was set to 63° C. The relative humidity in the tester was set to 50%. After performing the light resistance test, the transmittance of the cured film was measured, the maximum value of variation of transmittance was determined, and then the light resistance was evaluated based on the following standard. In a case of being evaluated as AA, A, or B according to the following standard, the light resistance is excellent.

In addition, the measurement of transmittance was performed 5 times for each sample, and the average value of the 3 times result except the maximum value and the minimum value was adopted. In addition, the maximum value of the variation of transmittance means a variation of transmittance of the cured film in a wavelength which has the largest variation of transmittance in a range of 400 to 700 nm before and after the light resistance test.

AA: maximum value of variation of transmittance was 3% or less.

A: maximum value of variation of transmittance was more than 3% and 5% or less.

B maximum value of variation of transmittance was more than 5% and 100 or less.

C: maximum value of variation of transmittance was more than 10.

TABLE 3

| | Spectral evaluation | | | | | Evaluation |
|---|---|---|---|---|---|---|
| | Wavelength | Wavelength | Wavelength | | Wavelength | result |
| | 1 | 2 | 3 | | difference 1 | Light |
| | (nm) | (nm) | (nm) | A⁴⁵⁰/A⁶²⁰ | (nm) | resistance |
| Example 1 | 509.5 | 484.3 | 551.2 | 1.85 | 104.8 | AA |
| Example 2 | 510.2 | 483.5 | 553.5 | 2.04 | 116 | A |
| Example 3 | 507.8 | 484.9 | 549.6 | 1.65 | 100 | AA |
| Example 4 | 506.3 | 484.6 | 546.1 | 1.49 | 97.5 | AA |
| Example 5 | 504.6 | 485.2 | 538.5 | 1.1 | 88 | A |
| Example 6 | 509.5 | 484.3 | 551.2 | 1.85 | 104.8 | AA |
| Example 7 | 509.5 | 484.3 | 551.2 | 1.85 | 104.8 | AA |
| Example 8 | 509.5 | 484.3 | 551.2 | 1.85 | 104.8 | AA |
| Example 9 | 509.5 | 484.3 | 551.2 | 1.85 | 104.8 | AA |
| Example 10 | 509.5 | 484.3 | 551.2 | 1.85 | 104.8 | AA |
| Example 11 | 509.5 | 484.3 | 551.2 | 1.85 | 104.8 | AA |
| Example 12 | 509.5 | 484.3 | 551.2 | 1.85 | 104.8 | AA |
| Example 13 | 509.5 | 484.3 | 551.2 | 1.85 | 104.8 | AA |
| Example 14 | 509.5 | 484.3 | 551.2 | 1.85 | 104.8 | AA |
| Example 15 | 509.5 | 484.3 | 551.2 | 1.85 | 104.8 | AA |
| Example 16 | 509.5 | 484.3 | 551.2 | 1.85 | 104.8 | AA |
| Example 17 | 509.5 | 484.3 | 551.2 | 1.85 | 104.8 | AA |
| Example 18 | 509.5 | 484.3 | 551.2 | 1.85 | 104.8 | AA |
| Example 19 | 509.5 | 484.3 | 551.2 | 1.85 | 104.8 | AA |
| Example 20 | 509.5 | 484.3 | 551.2 | 1.85 | 104.8 | AA |
| Example 21 | 509.5 | 484.3 | 551.2 | 1.85 | 104.8 | AA |
| Example 22 | 510.3 | 484.6 | 550.2 | 1.73 | 104.2 | AA |
| Example 23 | 511.8 | 484.1 | 552.3 | 1.97 | 110.5 | A |
| Example 24 | 509.6 | 484.3 | 546.6 | 1.54 | 98.3 | AA |
| Example 25 | 508.7 | 484.7 | 545.6 | 1.39 | 94.8 | AA |
| Example 26 | 506.4 | 485.3 | 544.7 | 1.26 | 92.6 | B |
| Example 27 | 509.9 | 484.5 | 550.7 | 1.79 | 104.5 | A |
| Comparative | 511.2 | 484.1 | 555.2 | 2.25 | 122.7 | A |
| Example 1 | | | | | | |
| Comparative | 512.6 | 484.6 | 553.3 | 2.08 | 118.3 | A |
| Example 2 | | | | | | |

The cure films obtained y using the coloring compositions o Examples were excellent in light resistance and spectral characteristics. In particular, the cured films obtained by using the coloring compositions of Examples had a high transmittance to light having a wavelength of 500 nm, and were excellent in sensitivity as a green pixel. Further, the transmittance at a wavelength of 620 nm was lower than that of Comparative Examples, and color separation property from blue was also excellent.

In addition, in a case where the absorbances of the coloring compositions of Examples were measured, the coloring compositions of Examples had a minimum absorbance in a wavelength range of 495 to 525 nm among absorbances to light having a wavelength of 400 to 700 nm, in a case where an absorbance to light having a wavelength of 450 nm was defined as 1, wavelengths at which an absorbance was 0.14 existed in a range of 474 to 494 nm and a range of 530 to 570 nm, respectively, and A⁴⁵⁰/A⁶²⁰, which is a ratio of an absorbance A⁴⁵⁰ to light having a wavelength of 450 nm and an absorbance A⁶²⁰ to light having a wavelength of 620 nm, was 1.08 to 2.05.

### Example 1001

A silicon wafer was coated with a coloring composition for forming a green pixel with a spin coating method so that the film thickness after film formation was 1.0 μm. Next, the coating film was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and then washed with pure water. Next, a green colored pattern (green pixel) was formed by heating at 200° C. for 5 minutes using a hot plate. In the same manner, a coloring composition 1 for forming a red pixel and a coloring composition 1 for forming a blue pixel were sequentially patterned to form a red colored pattern (red pixel) and a blue colored pattern (blue pixel), respectively, thereby forming a structure body. As the coloring composition for forming a green pixel, the coloring composition of Example 1 was used. The coloring composition 1 for forming a red pixel and the coloring composition 1 for forming a blue pixel will be described later.

The obtained structure body was incorporated into an organic electroluminescent display device according to a known method. This organic electroluminescent display device had a suitable image recognition ability.

### Example 1002

A silicon wafer was coated with a coloring composition for forming a green pixel with a spin coating method so that the film thickness after film formation was 1.0 μm. Next, the coating film was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and then washed with pure water. Next, a green colored pattern (green pixel) was formed by heating at 200° C. for 5 minutes using a hot plate. In the same manner, a coloring composition 1 for forming a red pixel and a coloring composition 2 for forming a blue pixel were sequentially patterned to form a red colored pattern (red pixel) and a blue colored pattern (blue pixel), respectively, thereby forming a structure body. As the coloring composition for forming a green pixel, the coloring composition of Example 1 was used. The coloring composition 1 for forming a red pixel and the coloring composition 2 for forming a blue pixel will be described later.

The obtained structure body was incorporated into an organic electroluminescent display device according to a known method. This organic electroluminescent display device had a suitable image recognition ability.

[Coloring Composition 1 for Forming Red Pixel]

A mixture having the following composition was stirred and mixed so as to be uniform, and then filtered through a 1.0 μm filter to produce the coloring composition 1 for forming a red pixel.

Pigment dispersion liquid DR-1 . . . 30.2 parts by mass

Pigment dispersion liquid DY-1 . . . 8.4 parts by mass

Resin solution 12 . . . 15.2 parts by mass

Polymerizable compound (ARONIX M-402, manufactured by TOAGOSEI CO., LTD.) . . . 0.7 parts by mass

Photopolymerization initiator (Irgacure OXE02, manufactured by BASF) . . . 0.3 parts by mass

PGMEA . . . 44.2 parts by mass

[Coloring Composition 1 for Forming Blue Pixel]

A mixture having the following composition was stirred and mixed so as to be uniform, and then filtered through a 1.0 μm filter to produce the coloring composition 1 for forming a blue pixel.

Pigment dispersion liquid DB-1 . . . 10.4 parts by mass

Pigment dispersion liquid DV-1 . . . 6.1 parts by mass

Resin solution 12 . . . 24.2 parts by mass

Polymerizable compound (ARONIX M-402, manufactured by TOAGOSEI CO., LTD.) . . . 0.7 parts by mass

Photopolymerization initiator (Irgacure OXE02, manufactured by BASF) . . . 0.3 parts by mass

PGMEA . . . 44.2 parts by mass

[Coloring Composition 2 for Forming Blue Pixel]

A mixture having the following composition was stirred and mixed so as to be uniform, and then filtered through a 1.0 μm filter to produce the coloring composition 2 for forming a blue pixel.

Salt-forming compound-containing resin solution DC-1 . . . 23.0 parts by mass

Pigment dispersion liquid DB-2 . . . 45.0 parts by mass

Resin solution 12 . . . 6.5 parts by mass

Polymerizable compound (trimethylolpropane triacrylate) . . . 4.1 parts by mass

Photopolymerization initiator (Irgacure OXE01, manufactured by BASF) . . . 1.3 parts by mass

PGMEA . . . 20.1 parts by mass

The pigment dispersion liquid DR-1 was prepared by the following method. 11.0 parts by mass of C. I. Pigment Red 269, 21.5 parts by mass of a resin solution 11, 1 part by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DR-1.

The pigment dispersion liquid DY-1 was prepared by the following method.

23.5 parts by mass of C. I. Pigment Yellow 139, 7 parts by mass of a resin solution 11, 3 parts by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DY-1.

The pigment dispersion liquid DB-1 was prepared by the following method.

11.0 parts by mass of C. I. Pigment Blue 15:6, 21.5 parts by mass of a resin solution 11, 1 part by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DB-1.

The pigment dispersion liquid DV-1 was prepared by the following method.

11.0 parts by mass of C. I. Pigment Violet 23, 21.5 parts by mass of a resin solution 11, 1 part by mass of a dispersant (manufactured by BASF, EFKA4300), and 66.5 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DV-1.

The salt-forming compound-containing resin solution DC-1 was prepared by the following method.

75.1 parts by mass of isopropyl alcohol was charged into a separable four-neck flask equipped with a thermometer, a stirrer, a distillation tube, and a cooler, and was heated to 75° C. under a nitrogen stream. 18.2 parts by mass of methyl methacrylate, 27.3 parts by mass of n-butyl methacrylate, 27.3 parts by mass of 2-ethylhexyl methacrylate, 15.0 parts by mass of hydroxyethyl methacrylate, 12.2 parts by mass of dimethylaminoethyl methyl chloride salt methacrylic acid, 23.4 parts by mass of methyl ethyl ketone, and 7.0 parts by mass of 2,2′-azobis(2,4-dimethylvaleronitrile) were mixed to be homogeneous, the mixture was charged into a dropping funnel, and the dropping funnel was attached to the above-described separable four-neck flask and dropwise addition was performed over 2 hours. Two hours after the dropwise addition, it was confirmed from the solid content that the polymerization yield was 98% or more and the weight-average molecular weight (Mw) was 7330, and the mixture was cooled to 50° C. Thereafter, 14.3 parts by mass of methanol was added thereto to obtain a resin B-1 having a cationic group in the side chain and having a resin component of 40 mass %. The ammonium salt value of the obtained resin was 32 mgKOH/g.

Next, 5 parts by mass of the resin B-1 having a cationic group in the side chain was added to 2000 parts by mass of water, and the mixture was sufficiently stirred and mixed, and heated to 60° C. to prepare a resin solution. Separately, 10 parts by mass of C. I. Acid red 289 was dissolved in 90 parts by mass of water to prepare an aqueous solution, and the solution was added dropwise to the resin solution. After the dropwise addition, the reaction was performed by stirring the mixture at 60° C. for 120 minutes. To confirm the end point of the reaction, the reaction solution was dropped onto a filter paper, and it was judged that the salt-forming compound was obtained with the end point where the blurring disappeared. After allowing to cool to room temperature with stirring, the salt composed of a counter anion of the resin having a cationic group in the side chain and a counter cation of C. I. Acid red 289 was removed by suction filtration and washing with water. Thereafter, the salt-forming compound remaining on the filter paper was dried by removing water with a dryer, thereby obtaining 32 parts by mass of a salt-forming compound (C-1) of C. I. Acid red 289 and the resin B-1 having a cationic group in the side chain.

Next, 11 parts by mass of the salt-forming compound (C-1), 40 parts by mass of a resin solution 11, and 49 parts by mass of PGMEA were mixed, and the mixture was filtered through a 5.0 μm filter to prepare the salt-forming compound-containing resin solution DC-1.

The pigment dispersion liquid DB-2 was prepared by the following method.

11 parts by mass of C. I. Pigment Blue 15:6, 40 parts by mass of a resin solution 11, 1 part by mass of a dispersant (manufactured by BASF, EFKA4300), and 48 parts by mass of PGMEA were mixed, and then using zirconia beads having a diameter of 1 mm, the mixture was dispersed for 5 hours with an Eiger mill (“Mini Model M-250 MKII” manufactured by Eiger Japan Co., Ltd.). Thereafter, the mixture was filtered through a filter having a pore size of 5 μm to prepare the pigment dispersion liquid DB-2.

The resin solution 11 was prepared by the following method.

196 parts by mass of PGMEA was charged into a reaction vessel in which a separable four-neck flask was equipped with a thermometer, a cooling pipe, a nitrogen gas introduction pipe, a dropping tube, and a stirrer, and was heated to 80° C., and after replacing the inside of the reaction vessel with nitrogen, from the dropping tube, a mixture of 37.2 parts by mass of n-butyl methacrylate, 12.9 parts by mass of 2-hydroxyethyl methacrylate, 12.0 parts by mass of methacrylic acid, 20.7 parts by mass of para-cumylphenol ethylene oxide-modified acrylate (ARONIX M110 manufactured by TOAGOSEI CO., LTD.), and 1.1 parts by mass of 2,2′-azobisisobutyronitrile was added dropwise thereto over 2 hours. After the dropwise addition, the reaction was continued for another 3 hours to obtain a resin (Mw=30000). After cooling to room temperature, the reactant was diluted with PGMEA to adjust the concentration of solid contents to 20 mass %, thereby preparing the resin solution 11.

The resin solution 12 was prepared by the following method.

207 parts by mass of PGMEA was charged into a reaction vessel in which a separable four-neck flask was equipped with a thermometer, a cooling pipe, a nitrogen gas introduction pipe, a dropping tube, and a stirrer, and was heated to 80° C., and after replacing the inside of the reaction vessel with nitrogen, from the dropping tube, a mixture of 20 parts by mass of methacrylic acid, 20 parts by mass of para-cumylphenol ethylene oxide-modified acrylate (ARONIX M110 manufactured by TOAGOSEI CO., LTD.), 45 parts by mass of methyl methacrylate, 8.5 parts by mass of 2-hydroxyethyl methacrylate, and 1.33 parts by mass of 2,2′-azobisisobutyronitrile was added dropwise thereto over 2 hours. After the dropwise addition, the reaction was continued for another 3 hours. Next, for the total amount of the obtained solution, nitrogen gas was stopped and dry air was injected for 1 hour, and the mixture was stirred and then cooled to room temperature. Thereafter, a mixture of 6.5 parts by mass of 2-methacryloyloxyethyl isocyanate (manufactured by SHOWA DENKO K.K., Karenz MOI), 0.08 parts by mass of dibutyltin laurate, and 26 parts by mass of cyclohexanone was added dropwise thereto at 70° C. over 3 hours. After the dropwise addition, the reaction was continued for another 1 hour to obtain a resin (Mw=18000). After cooling to room temperature, the reactant was diluted with PGMEA to adjust the concentration of solid contents to 20 mass %, thereby preparing the resin solution 12.

What is claimed is:

1. A coloring composition comprising:
a colorant;
a polymerizable compound; and
a photopolymerization initiator,
wherein the colorant includes at least one selected from Color Index Pigment Blue 15:3 or Color Index Pigment Blue 15:4, and Color Index Pigment Yellow 150, and contains 35 to 55 parts by mass of Color Index Pigment Blue 15:3 and Color Index Pigment Blue 15:4 in total with respect to 100 parts by mass of Color Index Pigment Yellow 150,
the coloring composition has a minimum absorbance in a wavelength range of 495 to 525 nm among absorbances to light having a wavelength of 400 to 700 nm,
in a case where an absorbance to light having a wavelength of 450 nm is defined as 1, wavelengths at which an absorbance is 0.14 exist in a range of 474 to 494 nm and a range of 530 to 570 nm, respectively, and
A⁴⁵⁰/A⁶²⁰, which is a ratio of an absorbance A⁴⁵⁰ to light having a wavelength of 450 nm and an absorbance A⁶²⁰ to light having a wavelength of 620 nm, is 1.08 to 2.05.

2. The coloring composition according to claim 1,
wherein, in a case where the absorbance to light having a wavelength of 450 nm is defined as 1, a difference between a wavelength on a long wavelength side where an absorbance is 0.4 and a wavelength on a short wavelength side where an absorbance is 0.4 is 80 to 118 nm.

3. The coloring composition according to claim 1,
wherein a total content of Color Index Pigment Blue 15:3, Color Index Pigment Blue 15:4, and Color Index Pigment Yellow 150 in the colorant is 80 to 100 mass %.

4. The coloring composition according to claim 1,
wherein a content of the colorant in a total solid content of the coloring composition is 20 mass % or more.

5. The coloring composition according to claim 1,
wherein the polymerizable compound includes a polymerizable compound having three or more ethylenically unsaturated bond-containing groups.

6. The coloring composition according to claim 1,
wherein the polymerizable compound includes a polymerizable compound having an ethylenically unsaturated bond-containing group and an alkyleneoxy group.

7. The coloring composition according to claim 1,
wherein the photopolymerization initiator contains an oxime compound.

8. The coloring composition according to claim 1,
wherein the photopolymerization initiator contains an oxime compound and a hydroxyalkylphenone compound.

9. The coloring composition according to claim 1, further comprising:
a resin including a repeating unit derived from a compound represented by Formula (I), 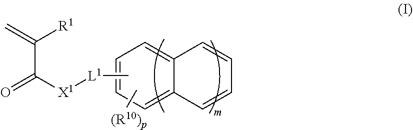
in the formula, X¹ represents O or NH,
R¹ represents a hydrogen atom or a methyl group,
L¹ represents a divalent linking group,
R¹⁰ represents a substituent,
m represents an integer of 0 to 2, and
p represents an integer of 0 or more.

10. The coloring composition according to claim 1, further comprising:
a compound including a furyl group.

11. The coloring composition according to claim 1,
wherein the coloring composition is a coloring composition for forming a green pixel of a color filter.

12. The coloring composition according to claim 1,
wherein the coloring composition is a coloring composition for a display device.

13. A cured film obtained by using the coloring composition according to claim 1.

14. A structure body comprising:
a green pixel;
a red pixel; and
a blue pixel,
wherein the green pixel is obtained by using the coloring composition according to claim 1.

15. A color filter comprising:
the cured film according to claim 13.

16. A display device comprising:
the cured film according to claim 13.
